(19) United States
(12) Patent Application Publication
(10) Pub. No.: US 2024/0278380 A1
(43) Pub. Date: Aug. 22, 2024

(54) POLISHING METHOD AND POLISHING APPARATUS

(71) Applicant: EBARA CORPORATION, Tokyo (JP)

(72) Inventors: Shinro OTA, Tokyo (JP); Masahiro HATAKEYAMA, Tokyo (JP)

(21) Appl. No.: 18/571,054

(22) PCT Filed: Jun. 14, 2022
(86) PCT No.: PCT/JP2022/023734

§ 371 Date: Dec. 15, 2023

(30) Foreign Application Priority Data
Jun. 22, 2021 (JP) 2021-102959
May 31, 2022 (JP) 2022-088291

(51) Int. Cl. B24B 37/013; B24B 37/04; B24B 37/10

(52) U.S. Cl. CPC B24B 37/013; B24B 37/042; B24B 37/10

(57) ABSTRACT

The present invention relates to a polishing method and a polishing apparatus for polishing a substrate, such as a wafer. This method includes: polishing a substrate W; producing a torque waveform while polishing the substrate W; and selecting one reference torque waveform from a plurality of reference torque waveforms accumulated before the polishing of the substrate W. Polishing the substrate W includes an asperity polishing process and a flat polishing process. The asperity polishing process includes: determining film thicknesses at measurements point on the substrate W based on a film thickness of reference film data calculated based on a first relational expression; comparing the torque waveform and the selected reference torque waveform; and determining whether the asperity polishing process should be terminated. The flat polishing process includes determining film thicknesses at measurement points on the substrate W based on a film thickness of reference film data calculated based on a second relational expression.

### TECHNICAL FIELD

The present invention relates to a polishing method and a polishing apparatus for polishing a substrate, such as a wafer.

### BACKGROUND ART

A planarization technique for a surface of a semiconductor device has been increasingly important in a manufacturing process of semiconductor devices. The most important technique in this surface planarization is chemical mechanical polishing (CMP). The chemical mechanical polishing (hereinafter referred to as CMP) is a process of polishing a substrate, such as a wafer, by placing the substrate in sliding contact with a polishing surface of a polishing pad while supplying a polishing liquid containing abrasive grains, such as silica (SiO₂), onto the polishing surface.

A polishing apparatus for performing CMP includes a polishing table configured to support a polishing pad having a polishing surface, and a polishing head configured to hold a substrate. Such a polishing apparatus is configured to provide relative motion between the polishing table and the polishing head, and is configured to press the substrate against the polishing surface of the polishing pad with the polishing head while a polishing liquid, such as slurry, is supplied onto the polishing surface of the polishing pad. A surface of the substrate is in sliding contact with the polishing surface in the presence of the polishing liquid, so that the substrate is polished to have a flat and mirror surface by a chemical action of the polishing liquid and a mechanical action of the abrasive grains contained in the polishing liquid.

In order to polish the substrate more flatly, conventional methods include measuring a film thickness while the substrate is polished, and controlling a distribution of residual film thicknesses in the substrate surface based on measurement values of the film thickness, and detecting a polishing end point of the substrate based on the measurement value of the film thickness. One method of measuring a film thickness during polishing of a substrate includes detecting a film-thickness signal of the substrate by a film-thickness sensor attached to the polishing table, and determining a film thickness based on the detected film-thickness signal and reference data obtained in advance.

### CITATION LIST

### Patent Literature

Patent document 1: International publication No. WO 2015/163164
Patent document 2: Japanese laid-open patent publication No. 2009-194134

### SUMMARY OF INVENTION

### Technical Problem

A substrate, such as a wafer, has a multilayered structure composed of different materials, such as a semiconductor, a conductor, and a dielectric material. Therefore, a substrate to be polished may have asperities in its surface due to a structure of layers underneath a film to be polished. With such a substrate, a polishing rate is not always constant. Therefore, the above-described film-thickness measuring method may not be able to accurately measure a film thickness. As a result, a uniformity of the film thickness or a detecting performance of an end point may be lowered.

It is therefore an object of the present invention to provide a polishing method and a polishing apparatus capable of improving a uniformity of a film thickness or a detecting performance of an end point.

### Solution to Problem

In an embodiment, there is provided a polishing method comprising: polishing a substrate by pressing the substrate with a polishing head against a polishing surface of a polishing pad while rotating a polishing table supporting the polishing pad; producing a torque waveform while polishing the substrate; and selecting one reference torque waveform from a plurality of reference torque waveforms accumulated before the polishing of the substrate, wherein producing the torque waveform comprises producing a torque waveform from a measurement value of a torque for rotating the polishing table, a measurement value of a torque for rotating the polishing head about an axis thereof, or a measurement value of a torque for oscillating the polishing head along the polishing surface, polishing the substrate includes an asperity polishing process of polishing the substrate before a film thickness of the substrate reaches an asperity-eliminated film-thickness, and a flat polishing process performed after the asperity polishing process, the asperity polishing process includes: determining a plurality of film thicknesses at a plurality of measurement points on the substrate based on a film thickness of reference film data calculated based on a first relational expression; and comparing the torque waveform with the selected reference torque waveform to determine whether the asperity polishing process should be terminated, and the flat polishing process includes determining a plurality of film thicknesses at a plurality of measurement points on the substrate based on a film thickness of reference film data calculated based on a second relational expression.

In an embodiment, selecting one reference torque waveform from the plurality of reference torque waveforms accumulated before the polishing of the substrate comprises selecting one reference torque waveform from the plurality of reference torque waveforms based on a film-thickness profile of the substrate before polishing and a type of the substrate.

In an embodiment, determining whether the asperity polishing process should be terminated comprises determining that the asperity polishing process should be terminated when a present torque of the torque waveform has reached an asperity-eliminated point estimated from the selected reference torque waveform.

In an embodiment, determining whether the asperity polishing process should be terminated includes: after a predetermined period of time has elapsed, comparing a shape of the torque waveform with a shape of the selected reference torque waveform till a polishing time corresponding to a present polishing time, and calculating a degree of coincidence of the shape of the torque waveform and the shape of the selected reference torque waveform; comparing the calculated degree of coincidence with a predetermined reference degree of coincidence, and when the calculated degree of coincidence is more than or equal to the predetermined reference degree of coincidence, calculating a difference between a polishing time at an asperity-eliminated point estimated from the selected reference torque waveform and the present polishing time; and determining that the asperity polishing process should be terminated when polishing time of the substrate has reached a time that is calculated by adding the present polishing time to the difference or a value obtained by multiplying the difference by a coefficient.

In an embodiment, the polishing method further comprises: after a predetermined period of time has elapsed, comparing a shape of the torque waveform with a shape of the selected reference torque waveform till a polishing time corresponding to a present polishing time, and calculating a degree of coincidence of the shape of the torque waveform and the shape of the selected reference torque waveform; and comparing the calculated degree of coincidence with a predetermined reference degree of coincidence, and when the calculated degree of coincidence is less than or equal to the predetermined reference degree of coincidence, changing a polishing condition.

In an embodiment, there is provided a polishing apparatus comprising: a polishing table configured to support a polishing pad; a table motor configured to rotate the polishing table; a polishing head having a plurality of pressure chambers configured to press a substrate against a polishing surface of the polishing pad; a film-thickness sensor configured to output a film-thickness signal that varies according to a film thickness of the substrate; a plurality of pressure regulators coupled to the plurality of pressure chambers, respectively; a torque measuring device configured to measure a torque for rotating the polishing table, a torque for rotating the polishing head, or a torque for oscillating the polishing head along the polishing surface; and an operation controller configured to control the polishing apparatus, wherein the operation controller is configured to produce a torque waveform from a measurement value of the torque for rotating the polishing table, a measurement value of the torque for rotating the polishing head, or a measurement value of the torque for oscillating the polishing head along the polishing surface, the operation controller is configured to select one reference torque waveform from a plurality of reference torque waveforms accumulated before polishing of the substrate, the operation controller is configured to perform an asperity polishing process of polishing the substrate before a film thickness of the substrate reaches an asperity-eliminated film-thickness, and a flat polishing process after the asperity polishing process, the operation controller is configured to, during the asperity polishing process, determine a plurality of film thicknesses at a plurality of measurement points on the substrate based on a film thickness of reference film data calculated based on a first relational expression, the operation controller is configured to, during the asperity polishing process, compare the torque waveform with the selected reference torque waveform and is configured to determine whether the asperity polishing process should be terminated, and the operation controller is configured to, during the flat polishing process, determine a plurality of film thicknesses at a plurality of measurement points on the substrate based on a film thickness of reference film data calculated based on a second relational expression.

In an embodiment, the operation controller is configured to select one reference torque waveform from the plurality of reference torque waveforms based on a film-thickness profile of the substrate before polishing and a type of the substrate.

In an embodiment, the operation controller is configured to determine that the asperity polishing process should be terminated when a present torque of the torque waveform has reached an asperity-eliminated point estimated from the selected reference torque waveform.

In an embodiment, the operation controller is configured to: after a predetermined period of time has passed, compare a shape of the torque waveform with a shape of the selected reference torque waveform till a polishing time corresponding to a present polishing time;

calculate a degree of coincidence of the shape of the torque waveform and the shape of the selected reference torque waveform; compare the calculated degree of coincidence with a predetermined reference degree of coincidence; calculate a difference between polishing time at an asperity-eliminated point estimated from the selected reference torque waveform and the present polishing time when the calculated degree of coincidence is more than or equal to the predetermined reference degree of coincidence; and determine that the asperity polishing process should be terminated when polishing time of the substrate has reached a time that is calculated by adding the present polishing time to the difference or a value obtained by multiplying the difference by a coefficient.

In an embodiment, the operation controller is configured to: after a predetermined period of time has passed, compare a shape of the torque waveform with a shape of the selected reference torque waveform till a polishing time corresponding to a present polishing time; calculate a degree of coincidence of the shape of the torque waveform and the shape of the selected reference torque waveform; compare the calculated degree of coincidence with a predetermined reference degree of coincidence; and instruct the polishing apparatus to change a polishing condition when the calculated degree of coincidence is less than or equal to the predetermined reference degree of coincidence.

In an embodiment, the film-thickness sensor comprises an optical film-thickness sensor or an eddy-current sensor.

In an embodiment, the polishing apparatus further comprises a film-thickness measuring device configured to measure a film thickness of the substrate, the film-thickness measuring device being attached to the polishing table.

In an embodiment, there is provided a polishing method comprising: polishing a substrate by pressing the substrate with a polishing head against a polishing surface of a polishing pad while rotating a polishing table supporting the polishing pad; producing a torque waveform indicating drive current of a motor required for moving the substrate relative to the polishing surface while polishing the substrate; inputting the torque waveform into an asperity-elimination predicting model; and outputting an asperity-elimination index of a surface of the substrate from the asperity-elimination predicting model.

In an embodiment, the asperity-elimination predicting model comprises a trained model constructed by: generating a plurality of training torque waveforms each indicating drive current of a motor required for moving a training substrate relative to the polishing surface while polishing the training substrate until surface asperities of the training substrate are eliminated; and performing machine learning using training data including the plurality of training torque waveforms.

In an embodiment, the training data further includes the number of substrates that have been polished previously using the polishing pad, and the polishing method includes inputting the number of substrates that have been polished previously using the polishing pad, in addition to the torque waveform, into the asperity-elimination predicting model.

In an embodiment, the polishing method further comprises: inputting the torque waveform into a polishing-end-point predicting model; and outputting a polishing-end-point index of the substrate from the polishing-end-point predicting model.

In an embodiment, the polishing method further comprises: virtually polishing the substrate in virtual space; and generating a virtual film-thickness profile of the substrate.

### Advantageous Effects of Invention

According to the present invention, the polishing apparatus of the embodiment changes the relational expression to be used for determining the film thickness of the substrate W during polishing depending on a surface configuration of the substrate W. Furthermore, the polishing apparatus compares the torque waveform produced during polishing of the substrate with the reference torque waveform obtained before polishing of the substrate, and determines a timing to change the relational expression. Therefore, the film thickness of the substrate during polishing is accurately measured even when the substrate has asperities in its surface. As a result, a uniformity of the film thickness and a detecting performance of an end point can be improved.

### BRIEF DESCRIPTION OF DRAWINGS

FIG. 1 is a plan view showing a polishing apparatus according to an embodiment of the present invention;

FIG. 2 is a schematic diagram showing an embodiment of a polishing module;

FIG. 3 is a diagram showing an example of a spectrum produced by an operation controller;

FIG. 4 is a schematic diagram showing an example of a plurality of measurement points on a surface of a substrate;

FIG. 5 is a graph showing a relationship between a film thickness of a reference wafer and polishing time when a polishing rate is constant;

FIG. 6 is a cross-sectional view showing an embodiment of a substrate having asperities in its surface;

FIG. 7A is a graph showing a relationship between a film thickness of a reference wafer having surface asperities in a polishing-target layer and polishing time;

FIG. 7B is a graph showing a relationship between a film thickness of a reference wafer having surface asperities in a polishing-target layer and polishing time;

FIG. 8 is a cross-sectional view of a polishing head shown in FIG. 2;

FIG. 9 is a schematic diagram showing another embodiment of the polishing module;

FIG. 10 is a schematic diagram showing still another embodiment of the polishing module;

FIG. 11 is a flowchart showing an embodiment of a polishing method for a reference substrate;

FIG. 12 is a flowchart showing an embodiment of a polishing method for a reference substrate;

FIG. 13 is a flowchart showing an embodiment of a polishing method for a substrate having asperities in its surface;

FIG. 14 is a flowchart showing an embodiment of a polishing method for a substrate having asperities in its surface;

FIG. 15 is a flowchart showing an embodiment of a polishing method for a substrate having asperities in its surface;

FIG. 16 is a flowchart showing an embodiment of a polishing method for a substrate having asperities in its surface;

FIG. 17 is a flowchart showing an embodiment of a polishing method for a substrate having asperities in its surface;

FIG. 18 is a flowchart showing an embodiment of a polishing method for a substrate having asperities in its surface.

FIG. 19 is a diagram showing an example of a torque waveform when a substrate having asperities in its surface is polished;

FIG. 20 is a diagram showing another example of the torque waveform when a substrate having asperities in its surface is polished;

FIG. 21 is a diagram showing another example of the torque waveform when a substrate having asperities in its surface is polished;

FIG. 22 is a flowchart showing an embodiment of a polishing method for a substrate having asperities in its surface after sufficient torque waveforms have been accumulated;

FIG. 23 is a flowchart showing an embodiment of a polishing method for a substrate having asperities in its surface after sufficient torque waveforms have been accumulated;

FIG. 24 is a flowchart showing an embodiment of a polishing method for a substrate having asperities in its surface after sufficient torque waveforms have been accumulated;

FIG. 25 is a flowchart showing an embodiment of a polishing method for a substrate having asperities in its surface after sufficient torque waveforms have been accumulated;

FIG. 26 is a flowchart showing an embodiment of a polishing method for a substrate having asperities in its surface after sufficient torque waveforms have been accumulated;

FIG. 27 is a flowchart showing an embodiment of a polishing method for a substrate having asperities in its surface after sufficient torque waveforms have been accumulated;

FIG. 28A is a cross-sectional view showing another embodiment of a substrate having asperities in its surface;

FIG. 28B is a cross-sectional view showing another embodiment of the substrate having the asperities in its surface;

FIG. 28C is a cross-sectional view showing another embodiment of the substrate having the asperities in its surface;

FIG. 29A is a cross-sectional view showing another embodiment of a substrate having asperities in its surface;

FIG. 29B is a cross-sectional view showing another embodiment of the substrate having the asperities in its surface;

FIG. 29C is a cross-sectional view showing another embodiment of the substrate having the asperities in its surface;

FIG. 30A is a cross-sectional view showing another embodiment of a substrate having asperities in its surface;

FIG. 30B is a cross-sectional view showing another embodiment of the substrate having the asperities in its surface;

FIG. 30C is a cross-sectional view showing another embodiment of the substrate having the asperities in its surface;

FIG. 31 is a schematic diagram showing another embodiment of the polishing apparatus;

FIG. 32 is a schematic diagram showing still another embodiment of the polishing apparatus;

FIG. 33 is a schematic diagram showing still another embodiment of the polishing apparatus;

FIG. 34 is a schematic diagram showing still another embodiment of the polishing apparatus;

FIG. 35 is a diagram illustrating an embodiment of a method of polishing a substrate having asperities in its surface;

FIG. 36 is a diagram illustrating an embodiment of a polishing method including predicting asperities elimination of a substrate using a trained model;

FIG. 37 is a diagram illustrating another embodiment of a polishing method including predicting elimination of asperities of a substrate using trained models; and

FIG. 38 is a diagram illustrating still another embodiment of the polishing method including predicting elimination of asperities of a substrate using trained models.

### DESCRIPTION OF EMBODIMENTS

Hereinafter, embodiments of the present invention will be described in detail with reference to the drawings.

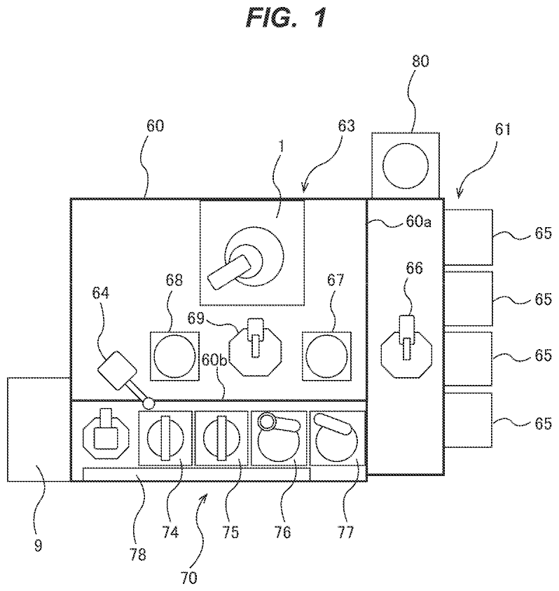

FIG. 1 is a plan view showing a polishing apparatus according to an embodiment of the present invention. This polishing apparatus is a substrate processing apparatus configured to be able to perform a series of processes of polishing, cleaning, and drying a surface of a substrate, such as a wafer. As shown in FIG. 1, the polishing apparatus includes an approximately rectangular-shaped housing 60. An interior of the housing 60 is partitioned by partition walls 60a and 60b into a load-unload section 61, a polishing section 63, and a cleaning section 70. The polishing apparatus includes a film-thickness measuring device 80 configured to measure a film thickness of the substrate, and an operation controller 9 configured to control operations of components of the polishing apparatus. The polishing section 63 is disposed between the load-unload section 61 and the cleaning section 70.

The film-thickness measuring device 80 is configured to measure the film thickness of the substrate utilizing optical interference, and can measure a film-thickness profile of the substrate. The film-thickness measuring device 80 of this embodiment is a stand-alone film-thickness measuring device. The film-thickness measuring device 80 of this embodiment measures the film thickness of the substrate when the substrate is in a stationary state. An example of such a film-thickness measuring device is an ITM (in-line thickness monitor).

The load-unload section 61 includes a plurality of load ports 65 on which substrate cassettes with a number of substrates housed therein are placed. A loader (transfer robot) 66 configured to be movable along the load ports 65 is disposed in the load-unload section 61. The loader 66 is configured to be able to access the substrates in the substrate cassettes placed on the load ports 65. The loader 66 is configured to transport the substrate to the film-thickness measuring device 80. Furthermore, the loader 66 has a function of reversing the substrate.

The polishing section 63 includes a polishing module 1 configured to polish the surface of the substrate, a first temporary base 67 and a second temporary base 68 on which the substrate is temporarily placed, and a transfer robot 69 configured to transport the substrate between the polishing module 1, the first temporary base 67, and the second temporary base 68. A swing transporter 64 configured to transport the substrate is disposed between the polishing section 63 and the cleaning section 70. The substrate that has been polished by the polishing section 63 is transported to the cleaning section 70 by the swing transporter 64.

The cleaning section 70 includes a first cleaning module 74, a second cleaning module 75, and a third cleaning module 76 each configured to clean the substrate polished by the polishing section 63. The cleaning section 70 further includes a drying module 77 configured to dry the substrate cleaned by these cleaning modules 74, 75, and 76. The cleaning section 70 further includes a linear transporter 78 configured to transport the substrate from the first cleaning module 74 to the second cleaning module 75, from the second cleaning module 75 to the third cleaning module 76, and from the third cleaning module 76 to the drying module 77.

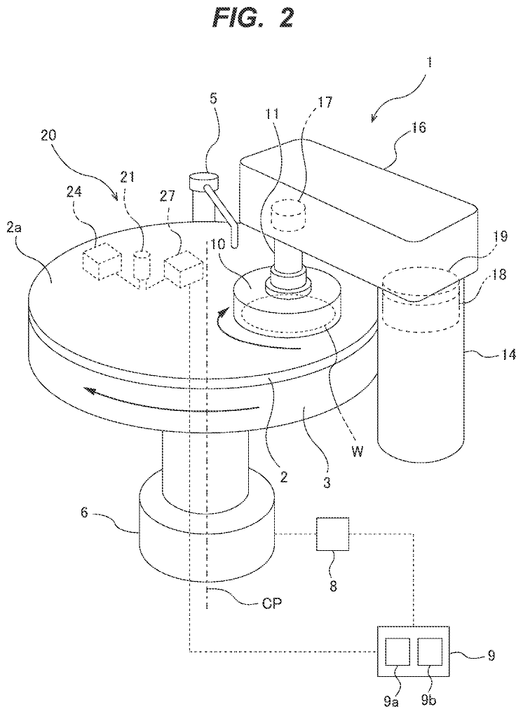

FIG. 2 is a schematic diagram showing an embodiment of the polishing module 1. The polishing module 1 includes a polishing table 3 configured to support a polishing pad 2, a polishing head 10 configured to press a substrate (e.g., a wafer) W against the polishing pad 2, a table motor 6 configured to rotate the polishing table 3, a polishing-liquid supply nozzle 5 configured to supply a polishing liquid, such as slurry, onto the polishing pad 2, a film-thickness sensor 20, and a torque measuring device 8. An upper surface of the polishing pad 2 constitutes a polishing surface 2a for polishing the substrate W.

The polishing module 1 further includes a support shaft 14, a oscillation arm 16 coupled to an upper end of the support shaft 14, a head shaft 11 attached to a free end of the oscillation arm 16, a polishing-head motor 17 coupled to the head shaft 11, and a oscillation motor 18 coupled to the oscillation arm 16 and configured to oscillate the polishing head 10 along the polishing surface 2a. The polishing head 10 is coupled to a lower end of the head shaft 11. In this embodiment, the polishing-head motor 17 is arranged in the oscillation arm 16, while in one embodiment, the polishing-head motor 17 may be arranged outside the oscillation arm 16.

The head shaft 11 is configured to be rotatable by the polishing-head motor 17. The polishing head 10 is coupled to the oscillation arm 16 via the head shaft 11. The rotation of the head shaft 11 causes the polishing head 10 to rotate about the head shaft 11 in a direction indicated by an arrow in the diagram. The head shaft 11 is coupled to a not-shown elevating device. The polishing head 10 is raised and lowered by the elevating device via the head shaft 11. The oscillation motor 18 is arranged in the support shaft 14. The oscillation arm 16 is configured to be able to swing (or rotate) about the support shaft 14. The polishing head 10 moves between a not-shown receiving position for the substrate W and a position above the polishing table 2 by the swing motion of the oscillation arm 16. In one embodiment, the oscillation arm 16 may be fixed to the support shaft 14, and the oscillation motor 18 may be coupled to the support shaft 14. The oscillation motor 18 may be configured to rotate the support shaft 14 and the oscillation arm 16 together about a rotation axis of the support shaft 14.

The polishing table 3 is coupled to the table motor 6, and the table motor 6 is configured to rotate the polishing table 3 and the polishing pad 2 in a direction indicated by an arrow in FIG. 2. The rotating directions of the polishing head 10 and the polishing table 3 are not limited to this embodiment.

The substrate W is polished as follows. The polishing liquid is supplied from the polishing-liquid supply nozzle 5 onto the polishing surface 2a of the polishing pad 2 on the polishing table 3, while the polishing table 3 and the polishing head 10 are rotated in the directions shown by the arrows in FIG. 2. The substrate W is pressed against the polishing surface 2a of the polishing pad 2 by the polishing head 10 in the presence of the polishing liquid on the polishing pad 2 while the substrate W is rotated by the polishing head 10. The surface of the substrate W is polished by a chemical action of the polishing liquid and a mechanical action of abrasive grains contained in the polishing liquid or the polishing pad 2.

In one embodiment, the substrate W may be polished while the polishing head 10 is oscillated by the oscillation motor 18 along the polishing surface 2a in a predetermined angle range (i.e., the polishing head 10 is in reciprocating rotational movement about the support shaft 14). An angle detector 19 is attached to the oscillation motor 18. This angle detector 19 is configured to detect a rotation angle of the oscillation arm 16 (i.e., a rotation angle of the polishing head 10 around the support shaft 14). The operation controller 9 controls the angle range of the oscillation motor 18 based on an angle signal from the angle detector 19. An example of the angle detector 19 is a rotary encoder.

The operation controller 9 includes a memory 9a storing programs therein, and a processor 9b configured to perform arithmetic operations according to instructions contained in the programs. The processor 9b includes a CPU (central processing unit), a GPU (graphic processing unit), or the like that performs arithmetic operations according to the instructions contained in the programs stored in the memory 9a. The memory 9a includes a main memory (e.g., a random access memory) that can be accessed by the processor 9b, and an auxiliary memory (e.g., a hard disk drive or a solid state drive) that stores data and the programs. The operation controller 9 is composed of at least one computer. However, the specific configuration of the operation controller 9 is not limited to this example.

The film-thickness measuring device 80, the table motor 6, the polishing-liquid supply nozzle 5, the film-thickness sensor 20, the torque measuring device 8, the polishing-head motor 17, the oscillation motor 18, the angle detector 19, and the elevating device (not shown) are electrically coupled to the operation controller 9. Operations of the film-thickness measuring device 80, the table motor 6, the polishing-liquid supply nozzle 5, the film-thickness sensor 20, the torque measuring device 8, the polishing-head motor 17, the oscillation motor 18, the angle detector 19, and the elevating device are controlled by the operation controller 9.

The torque measuring device 8 is coupled to the table motor 6. The torque measuring device 8 of this embodiment is configured to measure a torque for rotating the polishing table 3. During polishing of the substrate W, the polishing table 3 is driven by the table motor 6 so as to rotate at a constant speed. Therefore, when the torque required for rotating the polishing table 3 at the constant speed changes, drive current of the table motor 6 is changed.

The torque for rotating the polishing table 3 is a moment of force that rotates the polishing table 3 about its own axis CP. The torque for rotating the polishing table 3 corresponds to the drive current of the table motor 6. Therefore, in this embodiment, the torque measuring device 8 is a current measuring device configured to measure the drive current of the table motor 6. In one embodiment, the torque measuring device 8 may be constituted of at least a part of a motor driver configured to drive the table motor 6. In this case, the motor driver determines a current value required for rotating the polishing table 3 at the constant speed, and outputs the determined current value. The determined current value corresponds to the torque for rotating the polishing table 3. A measurement value of the torque for rotating the polishing table 3 (i.e., the value of the drive current of the table motor 6) is transmitted to the operation controller 9.

The film-thickness sensor 20 is configured to output a film-thickness signal that varies according to the film thickness of the substrate W. The film-thickness signal is a numerical value or data that directly or indirectly indicates the film thickness. The film-thickness sensor 20 of this embodiment is an optical film-thickness sensor. The optical film-thickness sensor is configured to direct light to the surface of the substrate W, measure an intensity of reflected light from the substrate W at each of wavelengths of the reflected light, and output intensity measurement data of the reflected light associated with the wavelengths. The intensity measurement data of the reflected light associated with the wavelengths is the film-thickness signal that varies according to the film thickness of the substrate W.

The film-thickness sensor 20 includes a light source 24 configured to emit the light, a spectrometer 27, and an optical sensor head 21 coupled to the light source 24 and the spectrometer 27. The optical sensor head 21, the light source 24, and the spectrometer 27 are attached to the polishing table 3, and rotate together with the polishing table 3 and the polishing pad 2. A position of the optical sensor head 21 is such that the optical sensor head 21 sweeps across the surface of the substrate W on the polishing pad 2 every time the polishing table 3 and the polishing pad 2 make one revolution.

The light emitted from the light source 24 is transmitted to the optical sensor head 21, which directs the light to the surface of the substrate W. The light is reflected off the surface of the substrate W, and the reflected light from the surface of the substrate W is received by the optical sensor head 21 and is further transmitted to the spectrometer 27. The spectrometer 27 decomposes the reflected light according to wavelength, and measures an intensity of the reflected light at each of the wavelengths. The intensity measurement data of the reflected light is transmitted to the operation controller 9. The operation controller 9 produces a spectrum of the reflected light from the intensity measurement data of the reflected light, and determines the film thickness of the substrate W based on this spectrum. The spectrum of the reflected light is expressed as a line graph (i.e., a spectral waveform) showing a relationship between the wavelength and the intensity of the reflected light. The intensity of the reflected light can also be represented as a relative value, such as a reflectance or a relative reflectance.

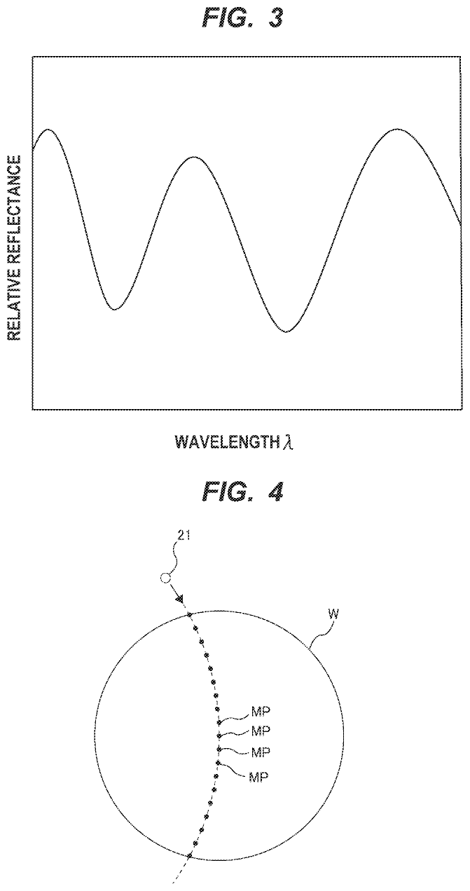

FIG. 3 is a diagram showing an example of the spectrum produced by the operation controller 9. The spectrum is expressed as a line graph (i.e., a spectral waveform) showing a relationship between the wavelength and the intensity of the light. In FIG. 3, horizontal axis represents the wavelength of the light reflected from the substrate, and vertical axis represents a relative reflectance derived from the intensity of the reflected light. The relative reflectance is an index value that represents the intensity of the reflected light. The relative reflectance is a ratio of the intensity of the light to a predetermined reference intensity. By dividing the intensity of the light (i.e., an actually measured intensity) at each of the wavelengths by the predetermined reference intensity, unwanted noises, such as a variation in the intensity inherent in an optical system or the light source of the apparatus, can be removed from the actually measured intensity.

The reference intensity is an intensity of light measured in advance at each of the wavelengths. The relative reflectance is calculated at each of the wavelengths. Specifically, the relative reflectance is determined by dividing the intensity of the light (the actually measured intensity) at each of the wavelengths by a corresponding reference intensity. The reference intensity is obtained by directly measuring an intensity of the light emitted from the optical sensor head 21 or irradiating a silicon substrate (i.e., a bare substrate) on which no film is formed with light and measuring an intensity of reflected light from the bare substrate.

In the actual polishing process, a dark level (which is a background intensity obtained under a condition that a light is cut off) is subtracted from the actually measured intensity to determine a corrected actually measured intensity. Further, the dark level is subtracted from the reference intensity to determine a corrected reference intensity. Then the relative reflectance is calculated by dividing the corrected actually measured intensity by the corrected reference intensity. Specifically, the relative reflectance R(λ) can be calculated by using the following equation (1).

$$R ( λ ) = \frac{E ( λ ) - D ( λ )}{B ( λ ) - D ( λ )} \qquad ( 1 )$$

Here, λ is the wavelength of the reflected light from the substrate, E(λ) is the intensity at the wavelength λ, B(λ) is the reference intensity at the wavelength λ, and D(λ) is the background intensity (i.e., dark level) at the wavelength λ measured under the condition that a light is cut off.

Every time the polishing table 3 makes one rotation, the optical sensor head 21 directs the light to the surface (i.e., a polishing-target surface) of the substrate W, and receives the reflected light from the substrate W. The reflected light is transmitted to the spectrometer 27. The spectrometer 27 decomposes the reflected light according to the wavelength, and measures the intensity of the reflected light at each of the wavelengths. The intensity measurement data of the reflected light is transmitted to the operation controller 9, and the operation controller 9 produces a spectrum as shown in FIG. 3 from the intensity measurement data of the reflected light. Further, the operation controller 9 determines the film thickness of the substrate W from the spectrum of the reflected light. The spectrum of the reflected light varies according to the film thickness of the substrate W. Therefore, the operation controller 9 can determine the film thickness of the substrate W from the spectrum of the reflected light. Hereinafter, in this specification, the spectrum generated from the reflected light from the substrate W to be polished may be referred to as a measurement spectrum.

The film-thickness sensor 20 of this embodiment is configured to output a plurality of intensity measurement data at a plurality of measurement points on the substrate W. In this embodiment, while the optical sensor head 21 sweeps across the substrate W once, the optical sensor head 21 emits the light to the plurality of measurement points on the substrate W and receives the reflected light from the plurality of measurement points. In this embodiment, only one optical sensor head 21 is provided in the polishing table 3, while a plurality of optical sensor heads 21 may be provided in the polishing table 3.

FIG. 4 is a schematic diagram showing an example of the plurality of measurement points on the surface (i.e., the polishing-target surface) of the substrate W. As shown in FIG. 4, the optical sensor head 21 directs the light to the plurality of measurement points MP every time the optical sensor head 21 sweeps across the substrate W, and receives the reflected light from the plurality of measurement points MP. Therefore, every time the optical sensor head 21 sweeps across the substrate W (i.e., every time the polishing table 3 makes one revolution), the operation controller 9 produces a plurality of measurement spectra of the reflected light from the plurality of measurement points MP, and determines (measures) a film thickness at each of the measurement points MP based on the plurality of measurement spectra. A position of each measurement point MP is determined based on an irradiation timing of the light, a rotation speed of the polishing table 3, a position of the polishing head 10, a rotation speed of the polishing head 10, etc.

The operation controller 9 is configured to determine (measure) the film thickness by comparing the measurement spectrum (also referred to as film measurement data) with a plurality of reference spectra (also referred to as reference film data). The operation controller 9 determines a reference spectrum having a shape closest to a shape of the measurement spectrum by comparing the measurement spectrum generated during polishing of the substrate W with the plurality of reference spectra, and determines a film thickness associated with the determined reference spectrum. The reference spectrum having the shape closest to the shape of the measurement spectrum is a spectrum with the smallest difference in relative reflectance between the reference spectrum and the measurement spectrum.

The plurality of reference spectra are obtained in advance while a reference wafer (or a reference substrate) is polished. The reference wafer (or the reference substrate) has the same multilayered structure as that of the substrate W to be polished (hereinafter the substrate W may be referred to as a target wafer or a target substrate). Each of the reference spectra is associated with a film thickness when the reference spectrum has been obtained. Specifically, each of the reference spectra has been obtained at a different film thickness, and the plurality of reference spectra correspond to a plurality of different film thicknesses. Therefore, a current film thickness of the substrate W can be determined (measured) by identifying the reference spectrum having the shape closest to the shape of the measurement spectrum.

An example of a process of obtaining the plurality of reference spectra will be described. First, a reference wafer having the same multilayered structure as that of the target substrate W is prepared. The reference wafer is transported to the film-thickness measuring device 80 (see FIG. 1), and an initial film thickness of the reference wafer is measured by the film-thickness measuring device 80. The initial film thickness of the reference wafer is a film thickness of the reference wafer before polishing. Next, the reference wafer is transported to the polishing module 1, and the reference wafer is polished while slurry as the polishing liquid is supplied onto the polishing pad 2. During polishing of the reference wafer, as described above, the light is directed to a surface of the reference wafer, and a spectrum of the reflected light from the reference wafer (i.e., a reference spectrum) is obtained. The reference spectrum is obtained every time the polishing table 3 makes one revolution. Therefore, a plurality of reference spectra are obtained during polishing of the reference wafer. After the polishing of the reference wafer is terminated, the reference wafer is again transferred to the film-thickness measuring device 80, and a film thickness (i.e., a final film thickness) of the polished reference wafer is measured.

The operation controller 9 calculates a film thickness corresponding to each of the reference spectra based on a relational expression indicating a correlation between a film thickness of the reference wafer and polishing time of the reference wafer. The reference spectrum is periodically obtained every time the polishing table 3 makes one revolution as described above, so that polishing time at which each of the reference spectra has been obtained can be calculated from a rotation speed and the number of rotations of the polishing table 3. Specifically, the operation controller 9 can calculate the film thickness corresponding to each of the reference spectra by inputting the polishing time at which each of the reference spectra has been obtained to the relational expression. In this way, the plurality of reference spectra corresponding to different film thicknesses are obtained.

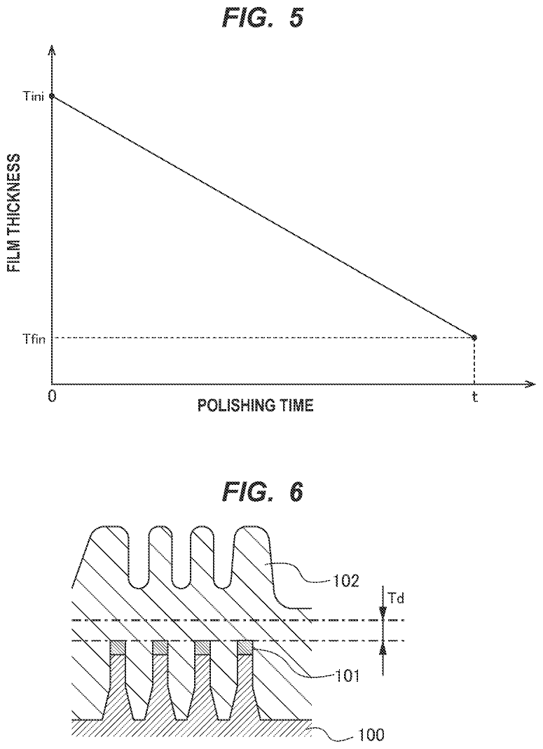

FIG. 5 is a graph showing a relationship between the film thickness of the reference wafer and the polishing time when a polishing rate is constant. When the polishing rate of the reference wafer is constant, the film thickness decreases linearly with the polishing time as shown in FIG. 5. In other words, when the polishing rate of the reference wafer is constant, the relational expression can be represented using a linear function including the polishing rate. When the polishing rate is constant, the polishing rate can be calculated by dividing a difference between the initial film thickness Tini and the final film thickness Tfin by polishing time t at which the final film thickness Tfin is reached. The operation controller 9 determines the relational expression based on the calculated polishing rate.

When the substrate W or the reference wafer has asperities in its surface (i.e., a surface to be polished), the polishing rate varies depending on a condition of a polishing-target layer.

When an underlying layer underneath the polishing-target layer has surface asperities or uneven surface, the polishing-target layer may also have surface asperities or uneven surface depending on the structure of the underlying layer. FIG. 6 is a cross-sectional view showing an embodiment of a substrate having surface asperities. The substrate shown in FIG. 6 has a stopper layer 101 made of silicon nitride (Si₃N₄) formed on protruding portions of a silicon (Si) layer 100 having the protruding portions and recess portions. The substrate shown in FIG. 6 further has a polishing-target layer 102 having surface asperities which is formed on the stopper layer 101. The polishing-target layer 102 of this embodiment is a dielectric film made of silicon dioxide (SiO₂). An example of the multilayered structure shown in FIG. 6 is shallow trench isolation (STI).

The polishing rate differs between recess portions and protruding portions in the surface, and this difference in polishing rate is expected to decrease as the surface asperities becomes smaller.

Since the protruding portions are polished preferentially before an asperity-eliminated film-thickness Td is reached as described above, a polishing rate of the polishing-target layer 102 before the asperity-eliminated film-thickness Td is reached is higher than a polishing rate after the asperity-eliminated film-thickness Td is reached. Therefore, the relational expression indicating the correlation between the film thickness of the reference wafer having the surface asperities in the polishing-target layer (i.e., the film thickness of the polishing-target layer) and the polishing time differs before and after an asperity-eliminated point.

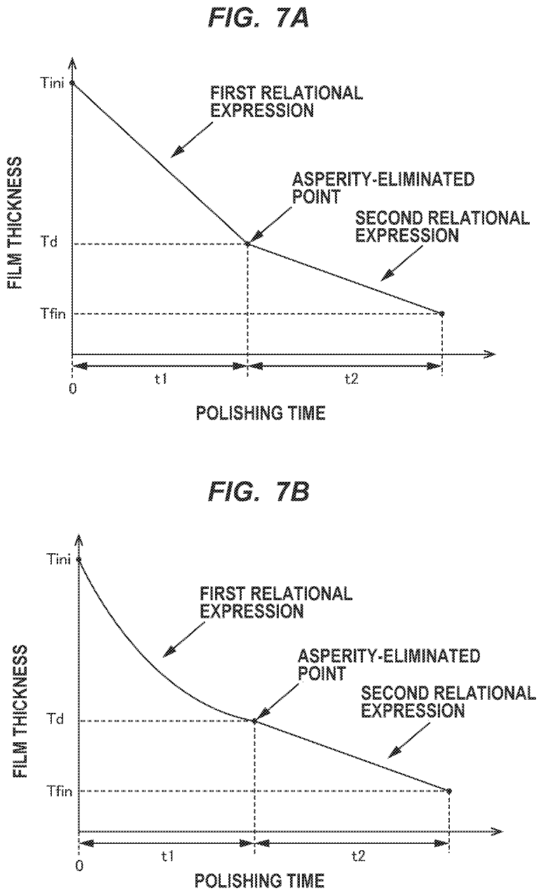

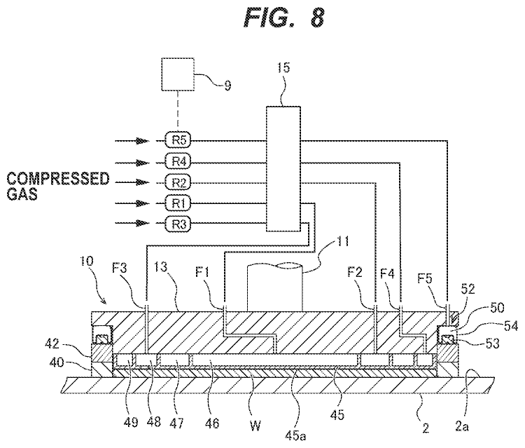

FIGS. 7A and 7B are graphs showing the relationship between the film thickness of the reference wafer having the surface asperities in the polishing-target layer and the polishing time. As shown in FIGS. 7A and 7B, when the polishing-target layer has the surface asperities, the relational expression indicating the correlation between the film thickness of the reference wafer (i.e., the film thickness of the polishing-target layer) and the polishing time includes a first relational expression indicating a correlation between the film thickness from the initial film thickness Tini to the asperity-eliminated film-thickness Td of the reference wafer (i.e., the film thickness of the polishing-target layer) and the polishing time, and a second relational expression indicating a correlation between the film thickness from the asperity-eliminated film-thickness Td to the final film thickness Tfin of the reference wafer (i.e., the film thickness of the polishing-target layer) and the polishing time.

The film thickness corresponding to each of the reference spectra is calculated based on the first relational expression and the second relational expression. In this embodiment, the polishing rate is constant from a time when the film thickness is the initial film thickness Tini to a time when the film thickness is the asperity-eliminated film-thickness Td. In this case, the second relational expression can be represented using a linear function including the polishing rate. When the polishing rate is constant, the polishing rate of the second relational expression can be calculated by dividing a difference between the asperity-eliminated film-thickness Td and the final film thickness Tfin by polishing time t2 between the time when the film thickness is the asperity-eliminated film-thickness Td and the time when the film thickness reaches the final film thickness Tfin. The operation controller 9 determines the second relational expression based on the calculated polishing rate. The asperity-eliminated film-thickness Td is measured by the film-thickness measuring device 80 when the film thickness has just reached the asperity-eliminated point.

In one embodiment, the asperity-eliminated film-thickness Td is determined as follows. A film-thickness profile of the reference wafer is measured by the film-thickness measuring device 80 at regular intervals until the film thickness of the reference wafer reaches the asperity-eliminated film-thickness Td. The operation controller 9 compares a film thickness of the protruding portions (e.g., an average film-thickness of the protruding portions) in the measured film-thickness profile with a predetermined protruding-portion threshold value, and determines the asperity-eliminated film-thickness Td which is a film thickness of the polishing-target layer when the film thickness of the protruding portions (e.g., the average film-thickness of the protruding portions) has reached the protruding-portion threshold value. Further, in one embodiment, a timing at which the film thickness of the reference wafer reaches the asperity-eliminated film-thickness Td may be detected based on a change in a torque current value (the drive current of the table motor 6, a drive current of the polishing-head motor 17, or a drive current of the oscillation motor 18, which will be described later) as a method other than the above-described method.

In the example shown in FIG. 7A, the polishing rate is constant from when the film thickness is the initial film thickness Tini to when the film thickness reaches the asperity-eliminated film-thickness Td. Therefore, the first relational expression shown in FIG. 7A can be represented using a linear function including the polishing rate. The polishing rate of the first relational expression shown in FIG. 7A can be calculated by dividing a difference between the initial film thickness Tini and the asperity-eliminated film-thickness Td by polishing time t1 between the time when the film thickness is the initial film thickness Tini and the time when the film thickness reaches the asperity-eliminated film-thickness Td. The operation controller 9 determines the first relational expression based on the calculated polishing rate.

In the example shown in FIG. 7B, the polishing rate gradually decreases until the film thickness reaches the asperity-eliminated film-thickness Td. An example of a method of determining the first relational expression in the example shown in FIG. 7B is described as follows. A plurality of film thicknesses are measured at different polishing times by the film-thickness measuring device 80 until the film thickness reaches the asperity-eliminated film-thickness Td. Measurement data points of the plurality of film thicknesses are plotted on a coordinate system with vertical axis representing the film thickness and horizontal axis representing the polishing time. A regression equation is determined by performing regression analysis on the plurality of data points. This regression equation is the first relational equation. The first relational expression in the example shown in FIG. 7B can be represented using, for example, a quadratic function.

In the examples shown in FIGS. 7A and 7B, the polishing rate is constant from when the film thickness reaches the asperity-eliminated film-thickness Td to when the film thickness reaches the final film thickness Tfin. However, the polishing rate may not be constant from when the film thickness reaches the asperity-eliminated film-thickness Td to when the film thickness reaches the final film thickness Tfin. Therefore, in one embodiment, a plurality of film thicknesses may be measured at different polishing times by the film-thickness measuring device 80 during a period of time from when the film thickness of the reference wafer reaches the asperity-eliminated film-thickness Td until the film thickness of the reference wafer reaches the final film thickness Tfin. Measurement data points of the plurality of film thicknesses may be plotted on a coordinate system with vertical axis representing the film thickness and horizontal axis representing the polishing time, and a regression equation may be determined by performing regression analysis on the plurality of data points. This regression equation may be used as the second relational equation. In one embodiment, the second relational expression can be represented using, for example, a quadratic function.

In one embodiment, the film-thickness sensor 20 may be an eddy-current sensor. The eddy-current sensor has a sensor coil configured to generate a magnetic flux that passes through a conductive film of the substrate W to generate an eddy current in the conductive film of the substrate W. The eddy-current sensor detects the eddy current that varies according to the film thickness of the substrate W and outputs an eddy-current signal. The eddy-current signal is a film-thickness signal that varies according to the film thickness of the substrate W. The eddy-current signal is transmitted to the operation controller 9. The operation controller 9 determines the film thickness of the substrate W based on the eddy-current signal. The film-thickness sensor 20 detects the eddy current every time the polishing table 3 makes one revolution, and as in the embodiment described with reference to FIG. 4, while the film-thickness sensor 20 sweeps across the substrate W once, the film-thickness sensor 20 detects the eddy current at a plurality of measurement points MP, and outputs eddy-current signals corresponding to the plurality of measurement points MP. The operation controller 9 determines the film thickness at each of the plurality of measurement points MP based on the plurality of eddy-current signals. Hereinafter, in this specification, the measurement value of the eddy-current signal (a magnitude of the eddy-current signal) detected from the target substrate may be referred to as a measurement eddy-current value.

The operation controller 9 is configured to determine the film thickness by comparing the measurement eddy-current value with reference eddy-current value. The operation controller 9 identifies a reference eddy-current value which is the closest to the measurement eddy-current value by comparing the measurement eddy-current value measured during polishing of the substrate W with a plurality of reference eddy-current values, and determines the film thickness associated with the identified reference eddy-current value. The reference eddy-current values are measurement values of the eddy-current signals detected from a reference wafer (i.e., a reference substrate) having the same multilayered structure as that of the target substrate. The plurality of reference eddy-current values are obtained in advance while the reference wafer (i.e., the reference substrate) is polished.

Hereinafter, in this specification, the measurement spectrum and the measurement eddy-current value may be collectively referred to as film measurement data, and the reference spectrum and the reference eddy-current value may be collectively referred to as reference film data. In other words, the film measurement data include film-thickness information of the target substrate obtained based on the film-thickness signal from the film-thickness sensor 20, and the reference film data include film-thickness information of the reference substrate obtained based on the film-thickness signal from the film-thickness sensor 20. A process of obtaining the reference eddy-current value, which will not be particularly described, is the same as the process of obtaining the reference spectrum described above. The above-described process of obtaining the reference spectrum can be applied to the process of obtaining the reference eddy-current value by alternative reading the reference spectrum as the reference eddy-current value.

Each of the reference eddy-current values is associated with a film thickness at which each of the reference eddy-current values has been obtained. The operation controller 9 calculates the film thickness corresponding to each of the reference eddy-current values based on a relational expression indicating a correlation between the film thickness of the reference wafer and the polishing time of the reference wafer. When the polishing-target layer of the reference wafer has surface asperities, the film thickness corresponding to each of the reference eddy-current values is calculated based on the first relational expression and the second relational expression, as in the embodiments described with reference to FIGS. 6 and 7.

When asperity-eliminated film-thicknesses Td of a plurality of target substrates differ due to a variation in initial film thickness or a difference in structure, a plurality of reference film data are obtained while each of the reference wafers having the same structure as that of each of the target substrates is polished before polishing of each of the target substrates. The operation controller 9 determines the film thickness of each target substrate by comparing the film measurement data obtained during polishing of each target substrate with the plurality of reference film data of each reference wafer corresponding to each target substrate.

Next, details of the polishing head 10 will be described. FIG. 8 is a cross-sectional view of the polishing head 10 shown in FIG. 2. As shown in FIG. 8, the polishing head 10 includes an elastic membrane 45 configured to press the substrate W against the polishing surface 2a of the polishing pad 2, a head body 13 configured to hold the elastic membrane 45, an annular drive ring 42 disposed below the head body 13, and an annular retainer ring 40 fixed to a lower surface of the drive ring 42. The elastic membrane 45 is attached to a lower portion of the head body 13. The head body 13 is fixed to the end of the head shaft 11. The head body 13, the elastic membrane 45, the drive ring 42, and the retainer ring 40 are configured to rotate together by the rotation of the head shaft 11. The retainer ring 40 and the drive ring 42 are configured to be vertically movable relative to the head body 13. The head body 13 is made of resin, such as engineering plastic (e.g., PEEK).

A lower surface of the elastic membrane 45 constitutes a substrate pressing surface 45a configured to press the substrate W against the polishing surface 2a of the polishing pad 2. The retainer ring 40 is arranged so as to surround the substrate pressing surface 45a, and the substrate W is surrounded by the retainer ring 40. Four pressure chambers 46, 47, 48, and 49 are provided between the elastic membrane 45 and the head body 13. The pressure chambers 46, 47, 48, and 49 are formed by the elastic membrane 45 and the head body 13. The central pressure chamber 46 has a circular shape, and the other pressure chambers 47, 48, and 49 have an annular shape. These pressure chambers 46, 47, 48, and 49 are in a concentric arrangement.

Gas delivery lines F1, F2, F3, and F4 are coupled to the pressure chambers 46, 47, 48, and 49, respectively. Ends of the gas delivery lines F1, F2, F3, and F4 are coupled to a compressed-gas supply source (not shown), which may be a utility provided in a factory in which the polishing apparatus is installed. Compressed gas, such as compressed air, is supplied into the pressure chambers 46, 47, 48, and 49 through the gas delivery lines F1, F2, F3, and F4, respectively. When the compressed gas is supplied into the pressure chambers 46 to 49, the elastic membrane 45 is inflated, and the compressed gas in the pressure chambers 46 to 49 presses the substrate W against the polishing surface 2a of the polishing pad 2 via the elastic membrane 45.

The gas delivery line F3 communicating with the pressure chamber 48 is coupled to a not-shown vacuum line, so that a vacuum can be formed in the pressure chamber 48. The elastic membrane 45 has an opening in a portion that forms the pressure chamber 48, so that the substrate W can be held by the polishing head 10 via vacuum suction by producing a vacuum in the pressure chamber 48. Further, the substrate W can be released from the polishing head 10 by supplying the compressed gas into the pressure chamber 48. The elastic membrane 45 is made of a rubber material with excellent strength and durability, such as ethylene propylene rubber (EPDM).

The retainer ring 40 is an annular member that contacts the polishing surface 2a. The retainer ring 40 is arranged so as to surround a periphery of the substrate W, and prevents the substrate W from slipping out from the polishing head 10 during polishing of the substrate W.

An upper portion of the drive ring 42 is coupled to an annular retainer-ring pressing device 52. The retainer-ring pressing device 52 applies a uniform downward load to the entire upper surface of the retainer ring 40 via the drive ring 42 to thereby press a lower surface of the retainer ring 40 against the polishing surface 2a.

The retainer-ring pressing device 52 includes an annular piston 53 fixed to the upper portion of the drive ring 42, and an annular rolling diaphragm 54 coupled to an upper surface of the piston 53. A retaining-ring pressure chamber 50 is formed inside the rolling diaphragm 54. This retaining-ring pressure chamber 50 is coupled to the compressed-gas supply source via a gas delivery line F5. The compressed gas is supplied into the retaining-ring pressure chamber 50 through the gas delivery line F5.

When the compressed gas is supplied from the compressed-gas supply source into the retaining-ring pressure chamber 50, the rolling diaphragm 54 pushes the piston 53 downward. The piston 53 pushes the drive ring 42 and the retainer ring 40 downward. In this way, the retainer-ring pressing device 52 presses the lower surface of the retainer ring 40 against the polishing surface 2a.

The gas delivery lines F1, F2, F3, F4, and F5 extend via a rotary joint 15 attached to the head shaft 11. The polishing module 1 further includes pressure regulators R1, R2, R3, R4, and R5. The pressure regulators R1, R2, R3, R4, and R5 are provided in the gas delivery lines F1, F2, F3, F4, and F5, respectively. The compressed gas from the compressed-gas supply source is independently supplied into the pressure chambers 46 to 49 and the retaining-ring pressure chamber 50 through the pressure regulators R1 to R5, respectively. The pressure regulators R1 to R5 are configured to regulate pressures of the compressed gas in the pressure chambers 46 to 49 and the retaining-ring pressure chamber 50, respectively. The pressure regulators R1 to R5 are coupled to the operation controller 9.

The pressure regulators R1 to R5 can independently change the internal pressures of the pressure chambers 46 to 49 and the retaining-ring pressure chamber 50. Therefore, pressing forces on four areas of the substrate W corresponding to the pressure chambers 46 to 49, i.e., a central portion, an inner intermediate portion, an outer intermediate portion, and an edge portion, against the polishing surface 2a, and a pressing force of the retainer ring 40 against the polishing pad 2 can be independently regulated. The gas delivery lines F1, F2, F3, F4, and F5 are coupled to vent valves (not shown), respectively, so that the pressure chambers 46 to 49 and the retaining-ring pressure chamber 50 can be vented to the atmosphere. In one embodiment, the elastic membrane 45 may form less than four pressure chambers or more than four pressure chambers.

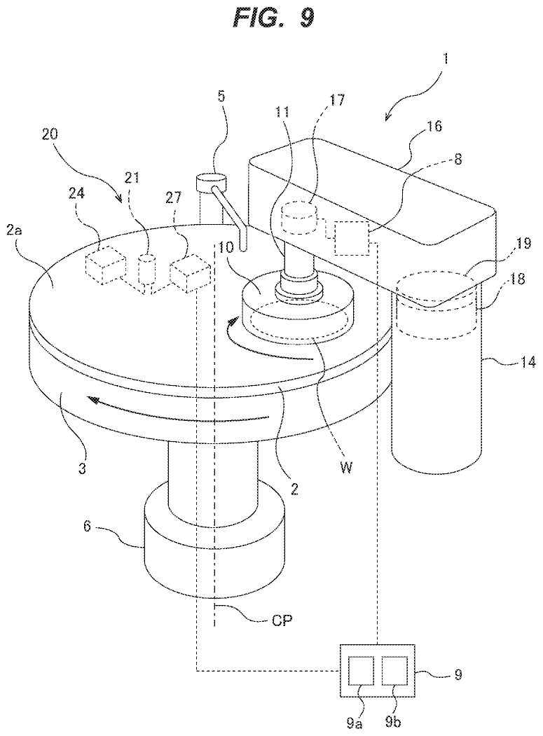

FIG. 9 is a schematic diagram showing another embodiment of the polishing module 1. Configurations and operations of this embodiment, which will not be particularly described, are the same as those of the embodiment shown in FIG. 2, and duplicated descriptions will be omitted. As shown in FIG. 9, in this embodiment, the torque measuring device 8 is coupled to the polishing-head motor 17. The torque measuring device 8 of this embodiment is configured to measure a torque for rotating the polishing head 10. During polishing of the substrate W, the polishing head 10 is driven by the polishing-head motor 17 via the head shaft 11 so as to rotate at a constant speed. Therefore, when the torque required for rotating the polishing head 10 at the constant speed changes, drive current of the polishing-head motor 17 is changed. In this embodiment, the torque measuring device 8 is disposed in the oscillation arm 16, while in one embodiment, the torque measuring device 8 may be disposed outside the oscillation arm 16.

The torque for rotating the polishing head 10 is a moment of force that rotates the polishing head 10 about the axis of the head shaft 11. The torque for rotating the polishing head 10 corresponds to the drive current of the polishing-head motor 17. Therefore, in this embodiment, the torque measuring device 8 is a current measuring device configured to measure the drive current of the polishing-head motor 17. In one embodiment, the torque measuring device 8 may be constituted of at least a part of a motor driver configured to drive the polishing-head motor 17. In this case, the motor driver determines a current value required for rotating the polishing-head motor 17 at the constant speed, and outputs the determined current value. The determined current value corresponds to the torque for rotating the polishing head 10. A measurement value of the torque for rotating the polishing head 10 (i.e., the drive current of the polishing-head motor 17) is transmitted to the operation controller 9.

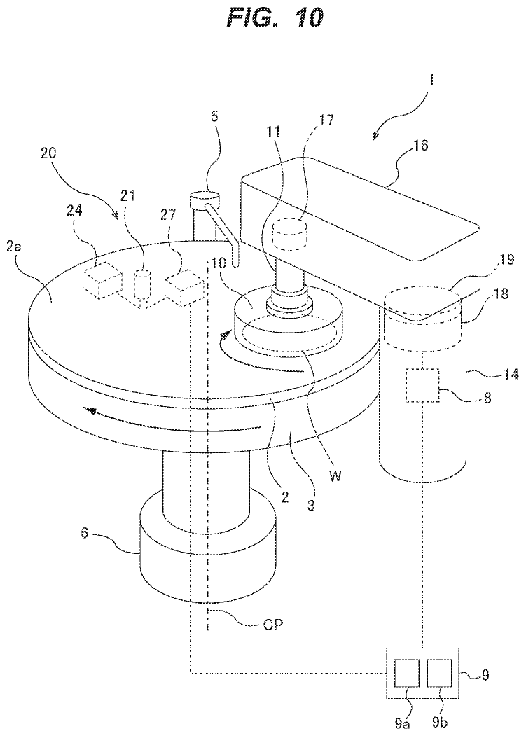

FIG. 10 is a schematic diagram showing still another embodiment of the polishing module 1. Configurations and operations of this embodiment, which will not be particularly described, are the same as those of the embodiment shown in FIG. 2, and duplicated descriptions will be omitted. As shown in FIG. 10, in this embodiment, the torque measuring device 8 is coupled to the oscillation motor 18. The torque measuring device 8 of this embodiment is configured to measure a torque for oscillating the polishing head 10 along the polishing surface 2a, i.e., a torque for rotating the polishing head 10 about the support shaft 14. When the substrate W is polished while the polishing head 10 is oscillated in a predetermined angle range, the oscillation motor 18 oscillates the polishing head 10 (reciprocally rotates the polishing head 10 about the support shaft 14) at a constant speed on the polishing surface 2a during polishing of the substrate W. Therefore, when the torque required for oscillating the polishing head 10 (reciprocally rotating the polishing head 10 about the support shaft 14) at the constant speed changes, drive current of the oscillation motor 18 changes. In this embodiment, the torque measuring device 8 is disposed in the support shaft 14, while in one embodiment, the torque measuring device 8 may be disposed outside the support shaft 14.

The torque for oscillating the polishing head 10 along the polishing surface 2a is a moment of force that causes the polishing head 10 to reciprocally rotate about the axis of the support shaft 14. The torque for oscillating the polishing head 10 corresponds to the drive current of the oscillation motor 18. Therefore, in this embodiment, the torque measuring device 8 is a current measuring device configured to measure the drive current of the oscillation motor 18. The current for reciprocally rotating the oscillation motor 18 at a constant speed is an alternating current. Therefore, in one embodiment, the torque measuring device 8 may calculate an effective value of the drive current of the oscillation motor 18 as the alternating current, and may output the calculated effective value as the measurement value of the drive current of the oscillation motor 18.

In one embodiment, the torque measuring device 8 may be constituted of at least a part of a motor driver configured to drive the oscillation motor 18. In this case, the motor driver determines a current value required for reciprocally rotating the oscillation motor 18 at the constant speed, and outputs the determined current value. The determined current value corresponds to the torque for oscillating the polishing head 10. In one embodiment, the motor driver configured to drive the oscillation motor 18 may determine an effective value of the current required for reciprocally rotating the oscillation motor 18 at the constant speed, and may output the effective value as a current value required for reciprocally rotating the oscillation motor 18 at the constant speed. A measurement value of the torque for oscillating the polishing head 10 along the polishing surface 2a (i.e., the drive current of the oscillation motor 18) is transmitted to the operation controller 9.

Next, a polishing method for a substrate having asperities in its surface (i.e., a surface to be polished) will be described. In the polishing method described below, the substrate W is polished while the asperity-eliminated point is estimated based on a torque waveform (i.e., a drive-current waveform of the table motor 6, a drive-current waveform of the polishing head motor 17, or a drive-current waveform of the oscillation motor 18). In order to perform this polishing method, it is necessary to accumulate a number of torque waveform data. In one embodiment, the substrate W is polished while the film thickness of the substrate W is measured by the film-thickness measuring device 80 until sufficient torque waveform data are accumulated for estimating the film thickness of the substrate W based on a present torque waveform.

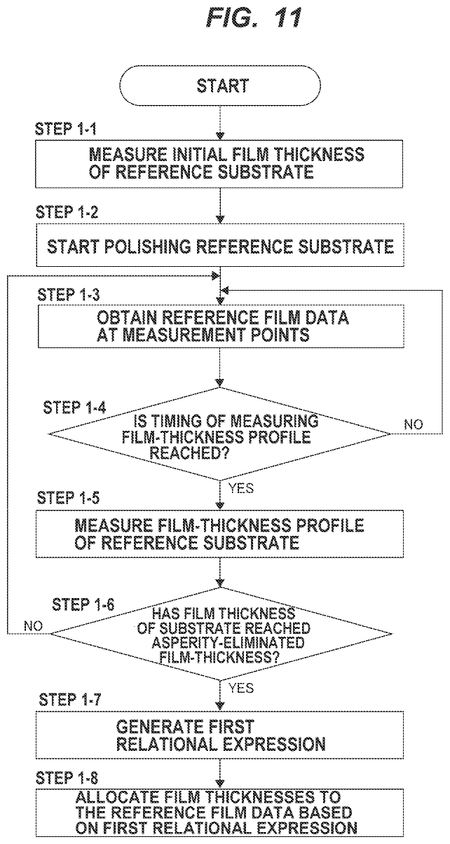

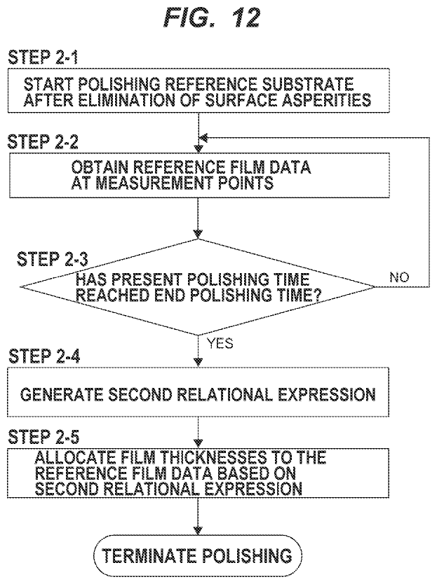

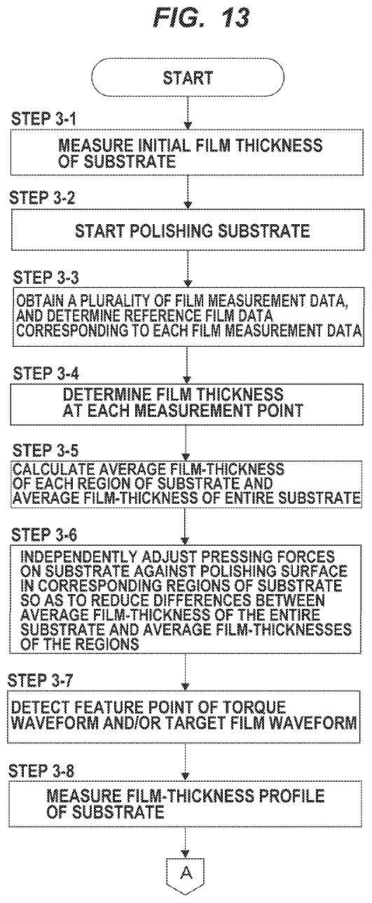

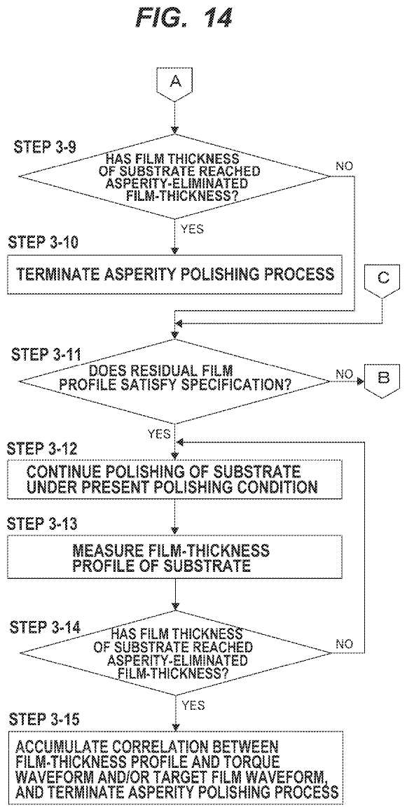

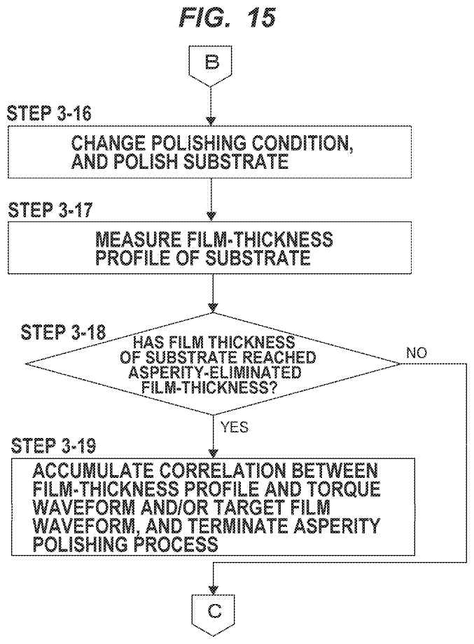

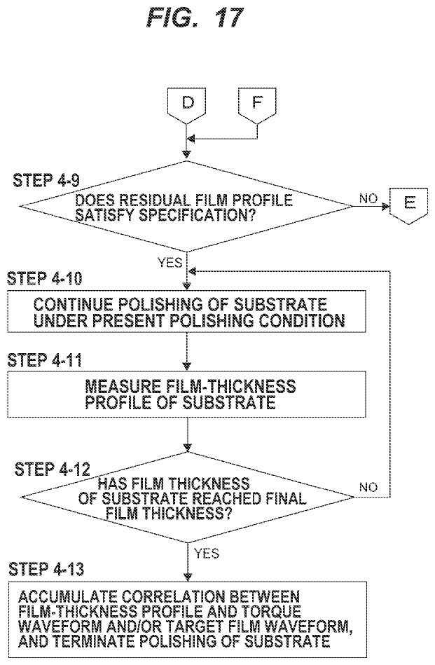

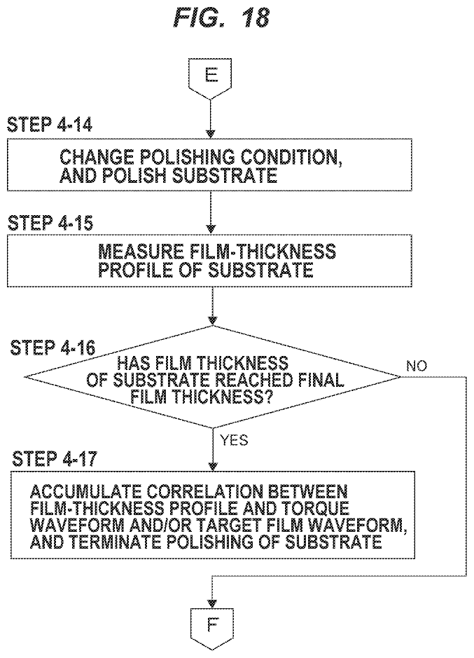

FIGS. 11 and 12 are flowcharts showing an embodiment of a polishing method for a reference substrate, and FIGS. 13 to 18 are flowcharts showing an embodiment of a polishing method for a substrate having asperities in its surface (i.e., a surface to be polished). The flowcharts shown in FIGS. 13 to 18 show a polishing method for the substrate W when sufficient torque waveform data have not been accumulated. An example of the substrate W to be polished is the substrate shown in FIG. 6, while the substrate to be polished is not limited to the substrate shown in FIG. 6. In this embodiment, before the polishing process for the substrate W, the reference substrate having the same multilayered structure as that of the substrate W as a target substrate is polished in order to obtain the reference film data, the first relational expression, and the second relational expression. The polishing apparatus polishes the reference substrate while obtaining a plurality of reference film data.

In this embodiment, the polishing apparatus polishes the reference substrate and the substrate W as the target substrate while measuring the torque for rotating the polishing table 3 (i.e., the drive current of the table motor 6), the torque for rotating the polishing head 10 about its own axis (i.e., the drive current of the polishing-head motor 17), or the torque for oscillating the polishing head 10 along the polishing surface 2a (i.e., the drive current of the oscillation motor 18). During the polishing process, the operation controller 9 generates a torque waveform from the measurement value of the above-mentioned torque. This torque waveform is a waveform over time (or a temporal waveform) of drive current of a motor required for moving a substrate relative to the polishing surface 2a of the polishing pad 2 against friction between the substrate and the polishing surface 2a. For example, the torque waveform is expressed as a line graph showing a relationship between the torque for rotating the polishing table 3 (or the polishing-head motor 17, or the oscillation motor 18) and the polishing time. Hereinafter, in this specification, a torque waveform of the torque for rotating the polishing table 3, a torque waveform of the torque for rotating the polishing head 10 about its own axis, and a torque waveform of the torque for oscillating the polishing head 10 along the polishing surface 2a may be collectively and simply referred to as torque waveform.

Hereinafter, one embodiment of the polishing method for the reference substrate will be described with reference to FIGS. 11 and 12. In steps 1-1 to 1-8 (see FIG. 11), a polishing process before elimination of the surface asperities of the reference substrate is performed. In step 1-1, an initial film thickness (i.e., a film thickness before polishing) of the reference substrate is measured by the film-thickness measuring device 80. The film-thickness measuring device 80 measures a plurality of film thicknesses (i.e., a film-thickness profile) at a plurality of measurement points on the reference substrate before polishing. In step 1-2, the polishing apparatus starts polishing the reference substrate. Specifically, the table motor 6 rotates the polishing table 3 together with the polishing pad 2 at a constant rotation speed, and the polishing head 10 rotates the reference substrate at a constant rotation speed. The polishing head 10 then presses the reference substrate against the polishing surface 2a of the polishing pad 2 to start polishing the reference substrate. In one embodiment, the reference substrate may be polished while the polishing head 10 is oscillated along the polishing surface 2a in a predetermined angle range by the oscillation motor 18.

In step 1-3, a plurality of reference film data (i.e., reference spectra or reference eddy-current values) are obtained at the plurality of measurement points on the reference substrate while the reference substrate is polished. The operation controller 9 periodically obtains the plurality of reference film data at the plurality of measurement points every time the film-thickness sensor 20 sweeps across the reference substrate (i.e., every time the polishing table 3 makes one revolution). The plurality of reference film data are stored in the memory 9a of the operation controller 9.

In step 1-4, the operation controller 9 determines whether a timing for measuring the film-thickness profile of the reference substrate is reached. Specifically, the operation controller 9 compares a present polishing time with a predetermined film-thickness measurement time (after performing step 1-5 which will be described later, the operation controller 9 compares a difference between the present polishing time and a polishing time when the film-thickness profile of the reference substrate has been last measured with the predetermined film-thickness measurement time). When the present polishing time has reached the predetermined film-thickness measurement time, the operation controller 9 temporarily stops polishing of the reference substrate. Thereafter, the reference substrate is transported to the film-thickness measuring device 80, and a film-thickness profile of the reference substrate is measured by the film-thickness measuring device 80 (step 1-5). The measurement data of the film-thickness profile is transmitted to the operation controller 9. When the present polishing time has not reached the predetermined film-thickness measurement time, the step 1-3 is performed again.

In step 1-6, the operation controller 9 determines whether the film thickness of the reference substrate corresponding to the measured film-thickness profile has reached the asperity-eliminated film-thickness. Specifically, the operation controller 9 compares the measured film thickness of the protruding portions of the reference substrate (e.g., an average film-thickness of the protruding portions) with a predetermined protruding-portion threshold value. When the film thickness of the protruding portions (e.g., the average film-thickness of the protruding portions) has reached the protruding-portion threshold value, the operation controller 9 determines that the film thickness of the reference substrate has reached the asperity-eliminated film-thickness. When the operation controller 9 determines that the film thickness of the substrate has reached the asperity-eliminated film-thickness, the operation controller 9 instructs the polishing apparatus to terminate the polishing operation before the elimination of the surface asperities, and performs step 1-7 which will be described later. When the operation controller 9 determines that the film thickness of the substrate has not reached the asperity-eliminated film-thicknesses, the step 1-3 and the subsequent steps are performed again. The film-thickness profile of the reference substrate is measured multiple times at different polishing times until the film thickness of the reference substrate reaches the asperity-eliminated film-thickness.

In one embodiment, the operation controller 9 may compare a film thickness of the recess portions (e.g., an average film-thickness of the recess portions) in the measured film-thickness profile with a predetermined recess-portion threshold value. When the film thickness of the recess portions (e.g., the average film-thickness of the recess portions) has reached the recess-portion threshold value, the operation controller 9 may determine that the film thickness of the reference substrate has reached the asperity-eliminated film-thickness. Further, in one embodiment, the operation controller 9 may calculate a difference between the film thickness of the protruding portions (e.g., the average film-thickness of the protruding portions) in the measured film-thickness profile and the film thickness of the recess portions (e.g., the average film-thickness of the recess portions) in the measured film-thickness profile, and may compare the calculated difference with a predetermined unevenness-difference threshold value. When the difference has reached the unevenness-difference threshold value, the operation controller 9 may determine that the film thickness of the reference substrate has reached the asperity-eliminated film-thickness.

Furthermore, in one embodiment, the operation controller 9 may calculate a dispersion of the plurality of film thicknesses at the plurality of measurement points on the reference substrate measured in the step 1-5, and may compare the dispersion with a predetermined dispersion threshold value. When the dispersion is more than (or less than) or equal to the dispersion threshold value, the operation controller 9 may determine that the film thickness of the reference substrate has reached the asperity-eliminated film-thickness. An example of the dispersion is a standard deviation of the plurality of film thicknesses at the plurality of measurement points.

As described above, during polishing of the reference substrate, the torque waveform is generated. In one embodiment, the operation controller 9 may determine whether the film thickness of the reference substrate has reached the asperity-eliminated film-thickness based on a change in the torque waveform (i.e., the torque waveform of the torque for rotating the polishing table 3, the torque waveform of the torque for rotating the polishing head 10 about its own axis, or the torque waveform of the torque for oscillating the polishing head 10 along the polishing surface 2a). In this case, the steps 1-4 and 1-5 may not be performed. Alternatively, when the operation controller 9 determines that the timing for measuring the film-thickness profile of the reference substrate is not reached in the step 1-4, the step 1-6 (i.e., determination whether the film thickness of the reference substrate has reached the asperity-eliminated film-thickness based on the change in the torque waveform) may be performed.

Specifically, the operation controller 9 calculates a differential value of the torque waveform, and compares the differential value with a predetermined differential threshold value. When the differential value is less than or equal to the differential threshold value, the operation controller 9 determines that the film thickness of the reference substrate has reached the asperity-eliminated film-thickness. The differential value of the torque waveform is determined by calculating a rate of change in the torque with respect to the polishing time (i.e., a rate of change in the torque).

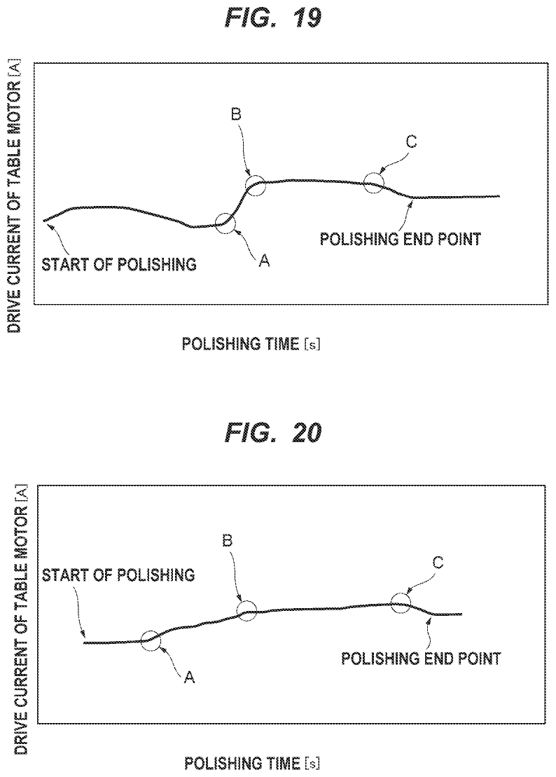

FIG. 19 is a diagram showing an example of a torque waveform when a substrate having asperities in its surface is polished. Specifically, FIG. 19 shows a waveform of drive current of the table motor 6 when the substrate shown in FIG. 6 is polished. As shown in FIG. 19, the drive current of the table motor 6 starts to rise after a certain period of time has elapsed from start of polishing. This is because a contact area between the recess portions and the polishing pad 2 increases when polishing of the protruding portions constituting the surface asperities progresses. A point in time when the drive current of the table motor 6 starts to rise is defined as a rising start point A.

When the polishing of the protruding portions further progresses, a slope (i.e., a differential value) of the torque waveform begins to gradually decrease. After the protruding portions are completely polished (i.e., after the torque waveform reaches an asperity-eliminated point B), the drive current of the table motor 6 no longer increases. Therefore, the asperity-eliminated point can be detected based on the differential value of the torque waveform. When an underlying layer of the polishing-target layer (e.g., the stopper layer 101 in the example shown in FIG. 6) begins to be exposed, the drive current of the table motor 6 begins to decrease. A point in time when the underlying layer of the polishing-target layer begins to be exposed is defined as an exposure start point C.

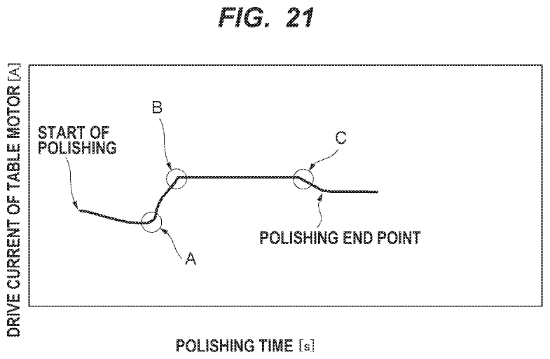

The torque waveform may have different shapes depending on the structure of the substrate to be polished or manufacturing variations. FIGS. 20 and 21 are diagrams showing other examples of the torque waveform when the substrate having asperities in its surface is polished. Specifically, FIG. 20 shows a waveform of drive current of the table motor 6 when a substrate in which a proportion of the protruding portions constituting the surface asperities is larger than that of the substrate of FIG. 6 is polished, and FIG. 21 shows a waveform of drive current of the table motor 6 when a substrate having deeper depth of the surface asperities than that of the substrate in FIG. 6 is polished.

It may be difficult to detect the asperity-eliminated point only from the change in the differential value, for example, when the torque waveform has a shape as shown in FIG. 20. Therefore, in one embodiment, the operation controller 9 may determine whether the film thickness of the reference substrate has reached the asperity-eliminated film-thickness based on a combination of the film-thickness profile measured by the film-thickness measuring device 80 and the above-described differential value. Examples of criteria for determining whether the film thickness has reached the asperity-eliminated film-thickness based on the combination of the film-thickness profile and the differential value is described as follows. Examples of determining that the film thickness of the reference substrate has reached the asperity-eliminated film-thickness based on the film-thickness profile described below include the above-described cases which include: the case where the film thickness of the protruding portions has reached the protruding-portion threshold value; the case where the film thickness of the recess portions has reached the recess-portion threshold value; the case where the difference between the protruding portions and the recess portions has reached the unevenness-difference threshold value; and the case where the dispersion of the plurality of film thicknesses at the plurality of measurement points is larger than (or less than) the dispersion threshold value.
A case where the differential value of the torque waveform is less than or equal to the differential threshold value, and when the operation controller 9 determines that the film thickness of the reference substrate has reached the asperity-eliminated film-thickness based on the film-thickness profile measured most recently from a point in time when the differential value of the torque waveform becomes less than or equal to the differential threshold value.
A case where the differential value of the torque waveform is less than or equal to the differential threshold value, and when the operation controller 9 determines that the film thickness of the reference substrate has reached the asperity-eliminated film-thickness based on the film-thickness profile measured immediately after the point in time when the differential value of the torque waveform becomes less than or equal to the differential threshold value.
A case where the differential value of the torque waveform is less than or equal to the differential threshold value, and when the operation controller 9 determines that the film thickness of the reference substrate has reached the asperity-eliminated film-thickness based on the film-thickness profile measured most recently from the point in time when the differential value of the torque waveform becomes less than or equal to the differential threshold value and determines that the film thickness of the reference substrate has reached the asperity-eliminated film-thickness based on the film-thickness profile measured immediately after the point in time when the differential value of the torque waveform becomes less than or equal to the differential threshold value.

Furthermore, in one embodiment, a correction value for the asperity-eliminated point may be calculated from a measuring result measured by the film-thickness measuring device 80. For example, in a case where the differential value of the torque waveform is less than or equal to the differential threshold value, but the operation controller 9 has been not able to determine that the film thickness of the reference substrate has reached the asperity-eliminated film-thickness from the film-thickness profile measured immediately after the point in time when the differential value of the torque waveform becomes less than or equal to the differential threshold value, the operation controller 9 may perform as follows. The operation controller 9 may calculate a difference between a polishing time at a point in time of measuring the film-thickness profile when the operation controller 9 determines that the film thickness of the reference substrate has reached the asperity-eliminated film-thickness and a polishing time when a threshold value of the torque waveform becomes less than or equal to the differential threshold value. When subsequent polishing of the reference substrate is performed, the operation controller 9 may determine the asperity-eliminated point by adding the above-mentioned difference to the polishing time at which the threshold value of the torque waveform becomes less than or equal to the differential threshold value.

Furthermore, in one embodiment, the operation controller 9 generates a reference film waveform from the reference film data (i.e., the reference spectra or the reference eddy-current values) during the polishing process for the reference substrate. The reference film waveform is expressed as a line graph showing a relationship between a physical quantity that indirectly represents the film thickness of the reference substrate included in the reference film data and the polishing time. The operation controller 9 generates the reference film waveform by plotting the physical quantities that indirectly represent the film thicknesses of the reference substrate on a coordinate system with vertical axis representing the physical quantity and horizontal axis representing the polishing time.

For example, the number of peaks and bottoms in the reference spectrum decreases as the polishing process progresses, while a rate of decrease in the number of peaks and bottoms is lowered as the asperity-eliminated point is approached. In one embodiment, the physical quantity that indirectly represents the film thickness of the reference substrate is the number of peaks and bottoms in the reference spectrum. Furthermore, in one embodiment, the physical quantity is the reference eddy-current value itself.

In one embodiment, the operation controller 9 may determine whether the film thickness of the reference substrate has reached the asperity-eliminated film-thickness based on a change in the reference film waveform. In this case, the steps 1-4 and 1-5 may not be performed. Alternatively, when the operation controller 9 determines that the timing of measuring the film-thickness profile of the reference substrate is not reached yet in the step 1-4, the step 1-6 (i.e., determining whether the film thickness of the reference substrate has reached the asperity-eliminated film-thickness based on the change in the reference film waveform) may be performed.

Specifically, the operation controller 9 calculates a differential value of the reference film waveform, and compares the differential value of the reference film waveform with a predetermined reference film threshold value. When the differential value of the reference film waveform is less than (or more than) or equal to the reference film threshold value, the operation controller 9 determines that the film thickness of the reference substrate has reached the asperity-eliminated film-thicknesses. The differential value of the reference film waveform is determined by calculating a rate of change in the physical quantity that indirectly represents the film thickness of the reference substrate included in the reference film data with respect to the polishing time (i.e., a rate of change in the physical quantity).

Furthermore, in one embodiment, the operation controller 9 may determine whether the film thickness of the reference substrate has reached the asperity-eliminated film-thickness based on a combination of the film-thickness profile measured by the film-thickness measuring device 80 and the differential value of the reference film waveform. Details of a determining method based on the combination of the film-thickness profile and the differential value of the reference film waveform, which will not be particularly described, are the same as those of the above-described method of determining whether the film thickness of the reference substrate has reached the asperity-eliminated film-thickness based on the combination of the film-thickness profile and the differential value of the torque waveform. The above-described determining method based on the combination of the film-thickness profile and the differential value of the torque waveform can be applied to the determining method based on the combination of the film-thickness profile and the differential value of the reference film waveform by replacing the differential value of the torque waveform with the differential value of the reference film waveform and replacing the differential threshold value with the reference film threshold value.

Furthermore, in one embodiment, machine learning may be applied to the process of determining the asperity-eliminated film-thickness based on the above-described torque waveform and/or the reference film waveform. Specifically, the torque measuring device 9 may determine the asperity-eliminated film-thickness using a trained model constructed by performing machine learning.

The machine learning is performed according to a learning algorithm that is an artificial intelligence (AI) algorithm, and the trained model that predicts the asperity-eliminated film-thickness is constructed by the machine learning. The learning algorithm for constructing the trained model is not particularly limited. For example, known learning algorithm, such as “supervised learning”, “unsupervised learning”, “reinforcement learning”, “neural network”, etc., can be employed as the learning algorithm. An example of the neural network is deep learning. The deep learning is a machine-learning method based on a neural network with multiple hidden layers (also referred to as middle layers).

In step 1-7, the operation controller 9 generates the first relational expression indicating a correlation between the film thickness of the reference substrate from the initial film thickness to the asperity-eliminated point and the polishing time of the reference substrate. The operation controller 9 calculates an average value of the plurality of initial film thicknesses measured in the step 1-1 and an average value of a plurality of film thicknesses (a plurality of asperity-eliminated film-thicknesses) at the plurality of measurement points at the point in time when the operation controller 9 determines that the film thickness has reached the asperity-eliminated film-thickness, and calculates a difference between the average value of the initial film thicknesses and the average value of the asperity-eliminated film-thicknesses. The operation controller 9 further calculates a polishing rate from the initial film thickness to the asperity-eliminated point by dividing the above-mentioned difference by the polishing time from the initial film thickness to the asperity-eliminated film-thickness. The operation controller 9 generates the first relational expression based on this polishing rate. In this case, the first relational expression is generated assuming that the polishing rate from the initial film thickness to the asperity-eliminated point is constant. In other words, the film thickness of the reference substrate can be determined by multiplying the polishing time by a coefficient which is the polishing rate.

In one embodiment, the operation controller 9 may generate the first relational expression based on film-thickness profiles measured at different polishing times. Specifically, the operation controller 9 calculates an index value of the film thickness of the reference substrate at each of the polishing times from the film-thickness profile measured at each of the polishing times. The index value may be determined by calculating an average value of a plurality of film thicknesses of the reference substrate at each of the polishing times. The operation controller 9 plots the index value of each of the film thicknesses on a coordinate system with vertical axis representing the film thickness and horizontal axis representing the polishing time. The operation controller 9 determines a regression equation by performing regression analysis on the plurality of index values plotted. The regression equation can be represented using, for example, a quadratic function. The operation controller 9 generates the first relational expression based on this regression equation. The first relational expression is stored in the memory 9a of the operation controller 9.

In step 1-8, the operation controller 9 allocates the film thicknesses to the plurality of reference film data based on the first relational expression. In other words, the operation controller 9 calculates the film thicknesses corresponding to the plurality of reference film data based on the first relational expression. Specifically, the operation controller 9 calculates the film thickness corresponding to each of the reference film data by applying the polishing time at which each of the reference film data has been obtained to the first relational expression.

In steps 2-1 to 2-5 (see FIG. 12), a polishing process after the elimination of the surface asperities of the reference substrate is performed. In step 2-1, the polishing apparatus starts polishing the reference substrate after the elimination of the surface asperities according to the method described above. In step 2-2, a plurality of reference film data at a plurality of measurement points on the reference substrate are obtained while the reference substrate is polished by the same method as the step 1-3. The plurality of reference film data are stored in the memory 9a of the operation controller 9.

In step 2-3, the operation controller 9 compares a present polishing time (polishing time from the step 2-1 to the present time) with a predetermined end polishing time. When the operation controller 9 determines that the present polishing time has reached the end polishing time, the operation controller 9 instructs the polishing apparatus to terminate the polishing of the reference substrate and performs step 2-4 which will be described later. When the operation controller 9 determines that the present polishing time does not reach the end polishing time, the operation controller 9 performs the step 2-2 and subsequent steps again.

The end polishing time is a polishing time at which the film thickness reaches the final film thickness, and is determined based on the asperity-eliminated film-thickness, the final film thickness, and a polishing rate after the elimination of the surface asperities. In one embodiment, the polishing rate of the reference substrate after the elimination of the surface asperities may be assumed to be constant. In this case, the polishing rate of the reference substrate after the elimination of the surface asperities is the same as the polishing rate of the reference substrate that does not have asperities in the polished surface, and therefore this polishing rate can be determined by experiment. The polishing rate of the reference substrate after the elimination of the surface asperities is stored in advance in the memory 9a.

In step 2-4, the operation controller 9 generates the second relational expression indicating a correlation between the film thickness of the reference substrate after the asperity-eliminated point and the polishing time of the reference substrate. The operation controller 9 generates the second relational expression based on the polishing rate after the elimination of the surface asperities which is obtained in advance, the asperity-eliminated film-thickness, and the final film thickness. The second relational expression is stored in the memory 9a of the operation controller 9.

In step 2-5, the operation controller 9 allocates the film thicknesses to the plurality of reference film data based on the second relational expression. In other words, the operation controller 9 calculates the film thicknesses corresponding to the plurality of reference film data based on the second relational expression. Specifically, the operation controller 9 calculates the film thickness corresponding to each of the reference film data by applying the polishing time at which each of the reference film data has been obtained to the second relational expression.

The polishing rate during a period of time from the asperity-eliminated film-thickness to the final film thickness may not be constant. Thus, the polishing of the reference substrate may be temporarily stopped at predetermined intervals during the steps 2-1 to 2-4, and the film-thickness profile of the reference substrate may be measured by the film-thickness measuring device 80. As a result, a plurality of film-thickness profiles are measured at different polishing times. In one embodiment, the operation controller 9 may generate the second relational expression based on the film-thickness profiles measured at the different polishing times. Specifically, the operation controller 9 calculates an index value of the film thickness of the reference substrate at each of the polishing times from the film-thickness profile measured at each of the polishing times. The index value may be determined by calculating an average value of a plurality of film thicknesses of the reference substrate at each of the polishing times. The operation controller 9 plots the index value of each of the film thicknesses on a coordinate system with vertical axis representing the film thickness and horizontal axis representing the polishing time. The operation controller 9 determines a regression equation by performing regression analysis on the plurality of plotted index values. The regression equation can be represented using, for example, a quadratic function. The operation controller 9 may generate the second relational expression based on this regression equation.

In one embodiment, the final film thickness of the reference substrate may be determined based on the film-thickness profile measured by the film-thickness measuring device 80. Specifically, the operation controller 9 comperes the film thickness of the reference substrate measured by the film-thickness measuring device 80 (e.g., an average value of the plurality of film thicknesses at the plurality of measurement points on the reference substrate) with a predetermined target film thickness. When the film thickness of the reference substrate has reached the target film thickness, the operation controller 9 may determine that the film thickness of the reference substrate has reached the final film thickness.

After the polishing process for the reference substrate, a polishing process for a substrate W as a target substrate is performed. Hereinafter, an embodiment of a polishing method for the substrate W when sufficient torque waveform data have not been accumulated will be described with reference to FIGS. 13 to 18. In steps 3-1 to 3-19 (see FIGS. 13 to 15), polishing of the substrate W is stopped at regular intervals, and a film thickness of the substrate is measured by the film-thickness measuring device 80. In steps 3-1 to 3-19, an asperity polishing process is performed. The asperity polishing process is a polishing process for the substrate W before the film thickness of the substrate W reaches the asperity-eliminated film-thickness, and includes a process of determining a plurality of film thicknesses at a plurality of measurement points based on the film thickness of the reference film data calculated based on the first relational expression. In this embodiment, during the polishing process, a torque waveform is produced from the above-described torque measurement values, and data of the torque waveform and/or a target film waveform, which will be described later, is accumulated in the memory 9a.

In step 3-1, an initial film thickness (i.e., a film thickness before polishing) of the substrate W is measured by the film-thickness measuring device 80. The film-thickness measuring device 80 measures a plurality of film thicknesses (i.e., a film-thickness profile) at a plurality of measurement points on the substrate W before polishing. In step 3-2, the polishing apparatus starts polishing the substrate W according to the above-described method. Specifically, the table motor 6 rotates the polishing table 3 together with the polishing pad 2 at a constant rotation speed, and the polishing head 10 rotates the substrate W at a constant rotation speed. The polishing head 10 then presses the substrate W against the polishing surface 2a of the polishing pad 2 to start polishing the substrate W. In one embodiment, the substrate W may be polished while the polishing head 10 is oscillated along the polishing surface 2a in a predetermined angle range by the oscillation motor 18.

In step 3-3, a plurality of film measurement data (i.e., measurement spectra or measurement eddy-current values) at a plurality of measurement points on the substrate W are obtained while the substrate W is polished. The operation controller 9 comperes the plurality of film measurement data with the plurality of reference film data, and determines (selects) one reference film data corresponding to each of the film measurement data from the plurality of reference film data (i.e., reference spectra or reference eddy-current values). The one reference film data to be determined or selected is a reference spectrum having the shape closest to the shape of the measurement spectrum (a reference spectrum with the smallest error from the measurement spectrum), or a reference eddy-current value that is closest to the measurement eddy-current value (a reference eddy-current value with the smallest error from the measurement eddy-current value).

In step 3-4, the operation controller 9 determines a film thickness at each of the measurement points. Specifically, the operation controller 9 allocates the film thickness of the reference film data determined in the step 3-3 which is calculated based on the first relational expression (i.e., the film thickness corresponding to the reference film data) to the film thickness at each of the measurement points. In other words, the operation controller 9 determines that the film thickness of the reference film data determined in the step 3-3 which is calculated based on the first relational expression is the film thickness at the measurement point where the film measurement data corresponding to the reference film data has been obtained.

In steps 3-5 and 3-6, the operation controller 9 instructs the plurality of pressure regulators R1 to R4 to adjust the polishing profile of the substrate W based on the film thicknesses at the plurality of measurement points on the substrate W. The specific processes are described as follows.

In step 3-5, the operation controller 9 calculates an average film-thickness of each of the above-described plurality of regions (in this embodiment, the four regions, i.e., the central portion, the inner intermediate portion, the outer intermediate portion, and the edge portion) of the substrate W and further calculates an average film-thickness of the entire substrate W. The average film-thickness of each of the regions is an average value of film thicknesses at a plurality of measurement points in each of the regions, and the average film-thickness of the entire substrate W is an average value of film thicknesses at all measurement points on the substrate W.

In step 3-6, the operation controller 9 instructs the pressure regulators R1 to R4 to independently adjust the pressing forces in corresponding regions of the substrate W against the polishing surface 2a so as to reduce differences between the average film-thickness of the entire substrate W and the average film-thickness of each of the above-described plurality of regions. As an example, the operation controller 9 compares the average film-thickness of each of the regions with the average film-thickness of the entire substrate W. When the film thickness of a certain region is larger than the average film-thickness of the entire substrate W, the operation controller 9 instructs the pressure regulator corresponding to that region (e.g., the pressure regulator R1 in the case when the region is the central portion) to increase an internal pressure of the corresponding pressure chamber (e.g., the pressure chamber 46).

In step 3-7, the operation controller 9 detects a feature point of the torque waveform and/or the target film waveform. The feature point is, for example, a point at which the slope of the waveform changes beyond a threshold value. Examples of the feature point is a point B in FIGS. 19 to 21. The operation controller 9 generates a target film waveform from the film measurement data (i.e., the measurement spectra or the measurement eddy-current values) during the polishing of the substrate W. This target film waveform is expressed as a line graph showing a relationship between a physical quantity that indirectly represents the film thickness of the substrate W included in the film measurement data and the polishing time. The operation controller 9 generates the target film waveform by plotting physical quantities that indirectly represent the film thicknesses of the substrate W on a coordinate system with vertical axis representing the physical quantity and horizontal axis representing the polishing time. For example, the number of peaks and bottoms in the measurement spectrum decreases as the polishing process progresses, while a rate of decrease is lowered as the asperity-eliminated point is approached. In one embodiment, the physical quantity that indirectly represents the film thickness of the substrate W is the number of peaks and bottoms of the measurement spectrum. Furthermore, in one embodiment, the physical quantity is the reference eddy-current value itself.

In step 3-8, the polishing of the substrate W is temporarily stopped, and a film-thickness profile of the substrate W is measured by the film-thickness measuring device 80. The film-thickness profile of the substrate W is measured multiple times at different polishing times until the film thickness of the substrate W reaches the asperity-eliminated film-thickness.

In step 3-9, the operation controller 9 checks a correlation between the film-thickness profile of the substrate W and the torque waveform and/or the target film waveform, and determines whether the film thickness of the substrate W has reached the asperity-eliminated film-thickness. When the operation controller 9 determines that the film thickness of the substrate W has reached the asperity-eliminated film-thickness, the operation controller 9 instructs the polishing apparatus to terminate the asperity polishing process (step 3-10).

When the operation controller 9 determines that the film thickness of the substrate W has not reached the asperity-eliminated film-thickness, the operation controller 9 determines whether the film-thickness profile (i.e., a residual film profile) of the substrate W satisfies a predetermined criterion (or specification) (step 3-11).

In step 3-12, when the operation controller 9 determines that the residual film profile satisfies the predetermined specification, the operation controller 9 instructs the polishing apparatus to continue the polishing of the substrate W under a present polishing condition. In the step 3-12, the same steps as the steps 3-3 to 3-7 are performed.

In step 3-13, the polishing of the substrate W is temporarily stopped, and a film-thickness profile of the substrate W is measured by the film-thickness measuring device 80. In step 3-14, the operation controller 9 determines whether the film thickness of the substrate W has reached the asperity-eliminated film-thickness according to the same method as the step 3-9. When the operation controller 9 determines that the film thickness of the substrate W has reached the asperity-eliminated film-thickness, the operation controller 9 accumulates the correlation between the film-thickness profile and the torque waveform and/or the target film waveform into the memory 9a of the operation controller 9, and instructs the polishing apparatus to terminate the asperity polishing process (step 3-15).

When the operation controller 9 determines that the residual film profile does not satisfy the predetermined specification in the step 3-11, the polishing condition is changed so as to improve the residual film profile (so as to satisfy the above-mentioned criterion), and the substrate W is polished (step 3-16). An example of the polishing condition is the internal pressure of each of the pressure chambers. For example, in order to improve the profile of the waveform, the operation controller 9 instructs at least one of the pressure regulators R1 to R4 to increase (or decrease) the internal pressure(s) of the corresponding pressure chamber(s).

In step 3-17, the polishing of the substrate W is temporarily stopped, and a film-thickness profile of the substrate W is measured by the film-thickness measuring device 80. In step 3-18, the operation controller 9 determines whether the film thickness of the substrate W has reached the asperity-eliminated film-thickness according to the same method as the step 3-9. When the operation controller 9 determines that the film thickness of the substrate W has reached the asperity-eliminated film-thickness, the operation controller 9 accumulates the correlation between the film-thickness profile and the torque waveform and/or the target film waveform into the memory 9a of the operation controller 9, and instructs the polishing apparatus to terminate the asperity polishing process (step 3-19). When the operation controller 9 determines that the film thickness of the substrate W has not reached the asperity-eliminated film-thickness in the step 3-18, the process flow returns to the step 3-11. In one embodiment, once the polishing condition has been changed, the process of determining whether the residual film profile satisfies the specification (the step 3-11) may be omitted. Specifically, when the operation controller 9 determines that the film thickness of the substrate W has not reached the asperity-eliminated film-thicknesses in the step 3-18, the process flow may return to the step 3-12.

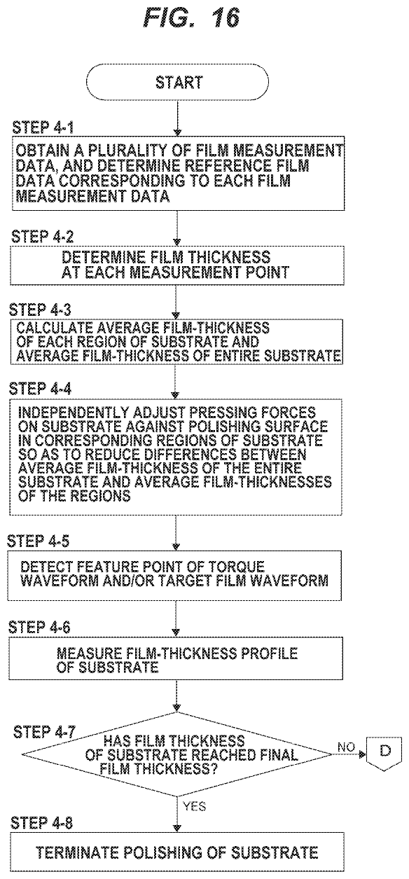

After the asperity polishing process is terminated, a flat polishing process of steps 4-1 to 4-17 are performed (see FIGS. 16 to 18). The flat polishing process includes a process of determining a plurality of film thicknesses at a plurality of measurement points on the substrate W based on the film thickness of the reference film data calculated based on the second relational expression. Processes of the steps 4-1 to 4-17, which will not be particularly described, are the same as those of the steps 3-3 to 3-19.

In step 4-2, the operation controller 9 allocates the film thickness of the reference film data determined in step 4-1 which is calculated based on the second relational expression (i.e., the film thickness corresponding to the reference film data) to the film thickness at each of the measurement points. In other words, the operation controller 9 determines that the film thickness of the reference film data determined in the step 4-1 which is calculated based on the second relational expression is the film thickness at the measurement point where the film measurement data corresponding to the reference film data has been obtained. The more specific process of the step 4-2 is the same as the step 3-4 except that the film thickness corresponding to the reference film data is determined based on the second relational expression.

In step 4-7, the operation controller 9 compares the film thickness of the substrate W with a predetermined final film thickness (a predetermined target film thickness). When the film thickness of the substrate W has reached the final film thickness, the operation controller 9 determines a polishing end point which is a point in time at which the film thickness has reached the final film thickness, and instructs the polishing apparatus to terminate the polishing of the substrate W (step 4-8). Specifically, the operation controller 9 compares the average film-thickness of the entire substrate W with the predetermined final film thickness. When the average film-thickness of the entire substrate W has reached the final film thickness, the operation controller 9 instructs the polishing apparatus to terminate the polishing of the substrate W.

If the polishing rate of the substrate W during the flat polishing process can be assumed to be constant, in the step 4-7, the operation controller 9 may compare a present polishing time (polishing time from the step 4-1 to the present time) with a predetermined end polishing time. When the operation controller 9 determines that the present polishing time has reached the end polishing time, the operation controller 9 may instruct the polishing apparatus to terminate the polishing of the substrate W. The end polishing time is a polishing time when the film thickness reaches the final film thickness, and is determined based on the asperity-eliminated film-thickness, the final film thickness, and a polishing rate after the elimination of the surface asperities. In steps 4-12 and 4-16, the same process as the step 4-7, i.e., a process of comparing the film thickness of the substrate W with the predetermined final film thickness, is performed. In steps 4-13 and 4-17, the operation controller 9 accumulates the correlation between the film-thickness profile and the torque waveform and/or the target film waveform into the memory 9a of the operation controller 9, and instructs the polishing apparatus to terminate the polishing of the substrate W.

After the above-described flat polishing process is terminated, or during the asperity polishing process, or during the flat polishing process, the operation controller 9 associates the measured film-thickness profile of the substrate W with the torque waveform and/or the target film waveform. In one embodiment, the operation controller 9 may determine the asperity-eliminated point B based on the measured film-thickness profile of the substrate W. Specifically, the operation controller 9 may determine the asperity-eliminated point B of the torque waveform based on the polishing time at which the film thickness of the substrate W has reached the asperity-eliminated film-thickness.

Further, the operation controller 9 stores the torque waveform and/or the target film waveform into the memory 9a in association with the initial film thickness data of the substrate W measured by the film-thickness measuring device 80, the film-thickness profile of the substrate W before polishing, the film-thickness profile of the substrate W during polishing, the asperity-eliminated film-thicknesses, etc.

The polishing apparatus may polish a plurality of substrates of the same type with different initial film thicknesses or a plurality of substrates having different shapes of uneven surface structures by the same method as the steps 3-1 to 3-19 and the steps 4-1 to 4-17 while generating torque waveforms. The polishing apparatus may determine the asperity-eliminated point of each of the torque waveforms based on the film-thickness profile measured during polishing of each of the substrates. The operation controller 9 may associate each of the torque waveforms and/or each of the target film waveforms generated during the polishing of each of the substrates with the film thickness data of the substrate to be polished. Examples of the film thickness data include a type of a substrate to be polished, initial film thickness data of a substrate to be polished, a film-thickness profile of a substrate before polishing, a film-thickness profile of a substrate during polishing, and asperity-eliminated film-thickness data. The data of the torque waveforms (i.e., the drive current waveforms of the table motor 6, the drive current waveforms of the polishing-head motor 17, or the drive current waveforms of the oscillation motor 18) and/or the target film waveforms associated with the film thickness data are accumulated into the memory 9a.

In one embodiment, in the above-described polishing process for the reference substrate (the steps 1-1 to 1-8 and the steps 2-1 to 2-5), the asperity-eliminated point of the torque waveform may be determined based on the film-thickness profile measured during polishing of the reference substrate. The operation controller 9 associates the torque waveform and/or the reference film waveform generated during the polishing of the reference substrate with the film thickness data of the reference substrate. The data of the torque waveform (i.e., the drive current waveform of the table motor 6, the drive current waveform of the polishing-head motor 17, or the drive current waveform of the oscillation motor 18) and/or the data of the reference film waveform associated with the film thickness data are accumulated into the memory 9a.

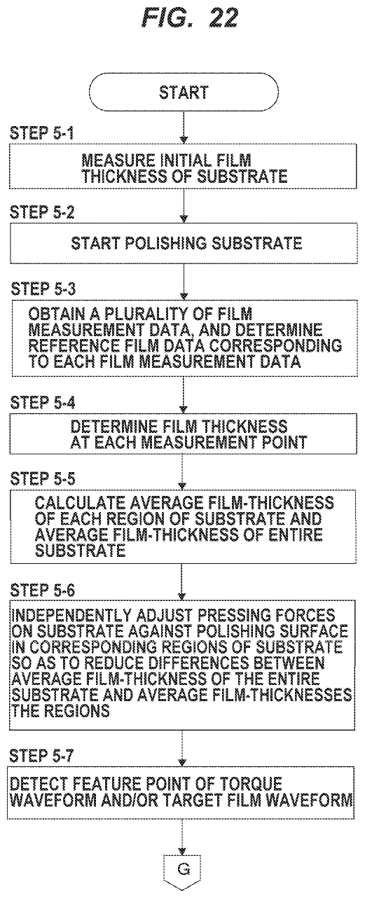

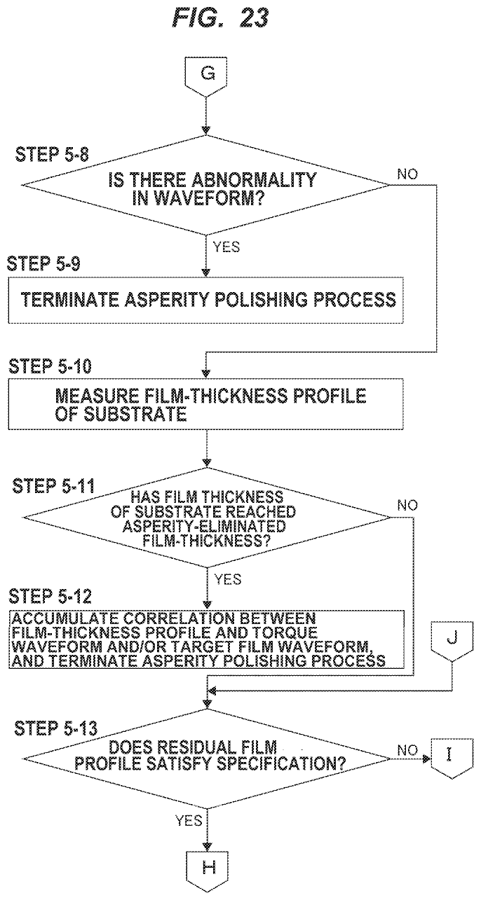

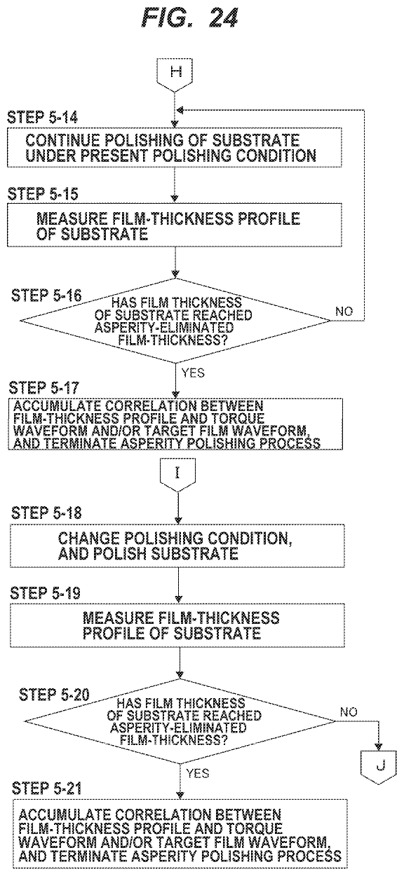

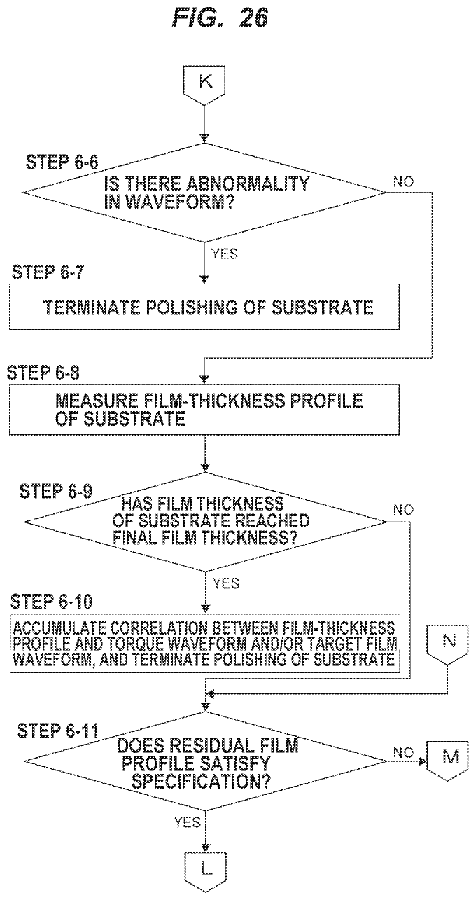

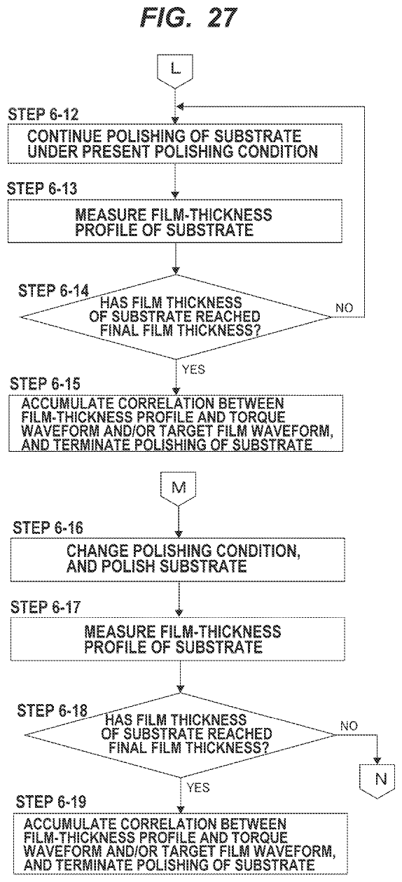

FIGS. 22 to 27 are flowcharts showing an embodiment of a polishing method for a substrate having asperities in its surface after sufficient torque waveforms have been accumulated. In this embodiment, the substrate is polished while the asperity-eliminated point is estimated based on the torque waveform. An example of the substrate W to be polished is the substrate shown in FIG. 6, while the substrate W to be polished is not limited to the substrate shown in FIG. 6. In this embodiment, the polishing apparatus polishes the reference substrate and the substrate W as a target substrate while measuring the torque for rotating the polishing table 3 (e.g., the drive current of the table motor 6), the torque for rotating the polishing head 10 about its own axis (e.g., the drive current of the polishing-head motor 17), or the torque for oscillating the polishing head 10 along the polishing surface 2a (e.g., the drive current of the oscillation motor 18). During the polishing process, the operation controller 9 produces a torque waveform from the measurement values of the torque. Hereinafter, a torque waveform which is obtained before the polishing process in this embodiment and is accumulated in the memory 9a may be referred to as a reference torque waveform. Further, in one embodiment, the operation controller 9 may produce a target film waveform during the polishing of the substrate W. Hereinafter, a reference film waveform and a target film waveform which are obtained before the polishing process in this embodiment and are accumulated in the memory 9a may be referred to as accumulated film waveform.

In steps 5-1 to 5-21 (see FIGS. 22 to 24), an asperity polishing process is performed. Processes of steps 5-1 to 5-6, which will not be particularly described, are the same as those of the steps 3-1 to 3-6.

In step 5-1, an initial film thickness of the substrate W to be polished (a film-thickness profile of the substrate W before polishing) is measured by the film-thickness measuring device 80. The operation controller 9 selects one reference torque waveform (or one accumulated film waveform) from a plurality of reference torque waveforms (or a plurality of accumulated film waveforms) based on the type of the substrate W and the measurement data (the film-thickness profile of the substrate W before polishing) measured by the film-thickness measuring device 80. Specifically, the operation controller 9 compares the measurement data measured by the film-thickness measuring device 80 and the type of substrate W with the film thickness data and the type of the substrate associated with each of the reference torque waveforms (or each of the accumulated film waveforms). The operation controller 9 selects a standard torque waveform which is a reference torque waveform whose type of the substrate is the same as the substrate W and whose film thickness data (specifically, the film-thickness profile before the polishing of the substrate used in producing of the reference torque waveform or the accumulated film waveform) is the closest to the measurement data measured by the film-thickness measuring device 80. In one embodiment, the operation controller 9 may select a standard torque waveform which is an accumulated film waveform whose type of the substrate is the same as the substrate W and whose film thickness data (specifically, the film-thickness profile before the polishing of the substrate used in producing of the accumulated film waveform) is the closest to the measurement data measured by the film-thickness measuring device 80. Hereinafter, in this specification, the torque waveform selected in the step 5-1 will be referred to as standard torque waveform, and the accumulated film waveform selected in the step 5-1 will be referred to as standard film waveform.

In step 5-4, the operation controller 9 determines a film thickness at each of the measurement points. Specifically, the operation controller 9 allocates the film thickness of the reference film data determined in the step 5-3 which is calculated based on the first relational expression (i.e., the film thickness corresponding to the reference film data) to the film thickness at each of the measurement points. In other words, the operation controller 9 determines that the film thickness of the reference film data determined in the step 5-3 which is calculated based on the first relational expression is the film thickness at the measurement point where the film measurement data corresponding to the reference film data has been obtained.

In step 5-7, the operation controller 9 detects a feature point of the torque waveform and/or the target film waveform. In step 5-8, the operation controller 9 checks whether there is an abnormality in the torque waveform and/or the target film waveform. In one embodiment, the operation controller 9 may check whether there is an abnormality in the torque waveform and/or the target film waveform by comparing correlations between film-thickness profiles accumulated in steps 5-12, 5-17, and 5-21, which will be described later, and the torque waveform and/or the target film waveform. When the operation controller 9 determines that there is no abnormality in the above-mentioned waveform, the operation controller 9 instructs the polishing apparatus to terminate the asperity polishing process (step 5-9). When the operation controller 9 determines that there is an abnormality in the above-mentioned waveform, steps 5-10 and subsequent steps are performed.

In step 5-10, the polishing of the substrate W is temporarily stopped, and a film-thickness profile of the substrate W is measured by the film-thickness measuring device 80. In one embodiment, the steps 5-7 to 5-10 may not be performed, and step 5-11 may be performed after the step 5-6. Furthermore, in one embodiment, step 5-11 may be performed after the step 5-7.

In step 5-11, the operation controller 9 determines whether the film thickness of the substrate W has reached the asperity-eliminated film-thickness, i.e., whether the asperity polishing process should be terminated. Specifically, the operation controller 9 compares the torque waveform (or the target film waveform) produced during the polishing with the standard torque waveform (or the standard film waveform), and determines whether the film thickness of the substrate W has reached the asperity-eliminated film-thickness, i.e., whether the asperity polishing process should be terminated. When the operation controller 9 determines that the asperity polishing process should be terminated, the operation controller 9 accumulates the correlation between the film-thickness profile and the torque waveform and/or the target film waveform into the memory 9a of the operation controller 9, and instructs the polishing apparatus to terminate the asperity polishing process (step 5-12). In one embodiment, when the torque waveform or the target film waveform is abnormal, the above-mentioned profile adjustment of the waveform may be performed after the asperity polishing process is terminated.

Details of the step 5-11 are described as follows. Specifically, the operation controller 9 determines that the asperity polishing process should be terminated when a present torque (or a present physical quantity, i.e., a physical quantity indirectly representing the film thickness of the substrate W included in the film measurement data) of the produced torque waveform (or the produced target film waveform) has reached the asperity-eliminated point that is estimated from the standard torque waveform (or the standard film waveform).

In one embodiment, the asperity polishing process may be terminated even if the present torque (or the present physical quantity) has not reached the asperity-eliminated point. For example, the operation controller 9 may determine that the asperity polishing process should be terminated when a magnitude of the present torque (or a magnitude of the present physical quantity) is less than or equal to a predetermined percentage (e.g., less than or equal to 130%) of a reference level of the standard torque waveform (or the standard film waveform), and/or when the present polishing time is more than or equal to 90% of the polishing time at the asperity-eliminated point that is estimated from the standard torque waveform (or the standard film waveform). The reference level is a predetermined threshold value for the magnitude of the torque (or the physical quantity).

In one embodiment, the operation controller 9 may determine that the asperity polishing process should be terminated when a magnitude of the present torque (or a magnitude of the present physical quantity) is less than or equal to a predetermined percentage of a reference level of an amount of change in a standard torque waveform differential value (or a standard film waveform differential value), and/or when the present polishing time is more than or equal to 90% of the polishing time at the asperity-eliminated point that is estimated from the amount of change in the standard torque waveform differential value (or the standard film waveform differential value). The reference level is a predetermined threshold value of the amount of change in the torque waveform differential value (or the differential value of the physical quantity).

Furthermore, in one embodiment, after a predetermined period of time has elapsed, the operation controller 9 may compare a shape of the produced torque waveform (or the produced target film waveform) with a shape of the standard torque waveform (or the standard film waveform) till a polishing time corresponding to the present polishing time, and may calculate a degree of coincidence of shape between these shapes. The operation controller 9 may compare the calculated degree of coincidence with a predetermined reference degree of coincidence. When the calculated degree of coincidence is more than or equal to the predetermined reference degree of coincidence, the operation controller 9 may calculate a difference between the polishing time at the asperity-eliminated point estimated from the standard torque waveform (or the standard film waveform) and the present polishing time. When the polishing time of the substrate W has reached a time that is calculated by adding the present polishing time to the above-mentioned difference or a value obtained by multiplying the above-mentioned difference by a coefficient, the operation controller 9 may determine that the asperity polishing process should be terminated. The degree of coincidence is represented as a numerical value from 0 to 1. The degree of coincidence is higher as the numerical value is closer to 1. The reference degree of coincidence is, for example, 0.8.

In one embodiment, when the calculated degree of coincidence of shape after the predetermined period of time has elapsed is less than or equal to the reference degree of coincidence, the operation controller 9 may determine that a polishing abnormality has occurred, and may instruct the polishing apparatus to temporarily stop the polishing of the substrate W. Thereafter, the substrate W may be transported to the film-thickness measuring device 80, and the film-thickness profile of the substrate W may be measured by the film-thickness measuring device 80.

Furthermore, in one embodiment, when the above-mentioned degree of coincidence of shape after the predetermined period of time has elapsed is less than or equal to the reference degree of coincidence, the operation controller 9 may instruct the polishing apparatus to change the polishing condition. For example, the operation controller 9 may instruct at least one of the pressure regulators R1 to R4 to increase (or decrease) the internal pressure(s) of the corresponding pressure chamber(s). As a result of changing the polishing condition, when the above-mentioned degree of coincidence of shape is more than or equal to the predetermined reference degree of coincidence, the operation controller 9 may calculate a difference between the polishing time at the asperity-eliminated point estimated from the standard torque waveform (or the standard film waveform) and the present polishing time. When the polishing time of the substrate W has reached a time that is calculated by adding the present polishing time to the above-mentioned difference or a value obtained by multiplying the above-mentioned difference by a coefficient, the operation controller 9 may instruct the polishing apparatus to terminate the asperity polishing process. In one embodiment, the operation controller 9 may determine whether the asperity polishing process should be terminated according to the method described in the step 3-9, i.e., the same method as the step 1-6.

When the operation controller 9 determines that the film thickness of the substrate W has not reached the asperity-eliminated film-thickness in the step 5-11, the operation controller 9 determines whether the film-thickness profile (i.e., the residual film profile) of the substrate W satisfies a predetermined criterion (or specification) (step 5-13).

In step 5-14, when the operation controller 9 determines that the residual film profile satisfies the specification, the operation controller 9 instructs the polishing apparatus to continue the polishing of the substrate W under a present polishing condition. In the step 5-14, the same steps as the steps 5-3 to 5-7 are performed.

In step 5-15, the polishing of the substrate W is temporarily stopped, and a film-thickness profile of the substrate W is measured by the film-thickness measuring device 80. In step 5-16, the operation controller 9 determines whether the film thickness of the substrate W has reached the asperity-eliminated film-thickness according to the same method as the step 5-11. When the operation controller 9 determines that the film thickness of the substrate W has reached the asperity-eliminated film-thickness, the operation controller 9 accumulates the correlation between the film-thickness profile and the torque waveform and/or the target film waveform into the memory 9a of the operation controller 9, and instructs the polishing apparatus to terminate the asperity polishing process (step 5-17).

When the operation controller 9 determines that the residual film profile does not satisfy the specification in the step 5-13, the polishing condition is changed so as to improve the residual film profile (so as to satisfy the above-mentioned criterion), and the substrate W is polished (step 5-18). An example of the polishing condition is the internal pressure of each of the pressure chambers. For example, in order to improve the profile of the waveform, the operation controller 9 instructs at least one of the pressure regulators R1 to R4 to increase (or decrease) the internal pressure(s) of the corresponding pressure chamber(s).

In step 5-19, the polishing of the substrate W is temporarily stopped, and a film-thickness profile of the substrate W is measured by the film-thickness measuring device 80. In step 5-20, the operation controller 9 determines whether the film thickness of the substrate W has reached the asperity-eliminated film-thickness by the same method as the step 5-11. When the operation controller 9 determines that the film thickness of the substrate W has reached the asperity-eliminated film-thickness, the operation controller 9 accumulates the correlation between the film-thickness profile and the torque waveform and/or the target film waveform into the memory 9a of the operation controller 9, and instructs the polishing apparatus to terminate the asperity polishing process (step 5-21). When the operation controller 9 determines that the film thickness of the substrate W has not reached the asperity-eliminated film-thickness in the step 5-20, the process flow returns to the step 5-13. In one embodiment, once the polishing condition has been changed, the process of determining whether the residual film profile satisfies the specification (the step 5-13) may be omitted. Specifically, when the operation controller 9 determines that the film thickness of the substrate W has not reached the asperity-eliminated film-thicknesses in the step 5-20, the step 5-14 and subsequent steps may be performed.

In one embodiment, the steps 5-15 and 5-19 may not be performed, and the steps 5-16 and 5-20 may be performed after the steps 5-14 and 5-18. Furthermore, in one embodiment, when the step 5-10 is not performed and when the operation controller 9 determines that the film thickness of the substrate W has not reached the asperity-eliminated film-thicknesses in the step 5-11, the steps 5-14 to 5-17 may be performed after the step 5-11. In this case, the step 5-15 may be omitted.

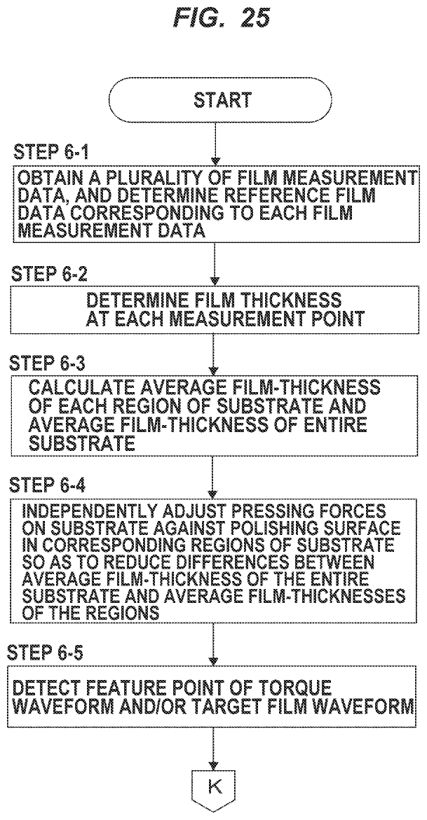

After the asperity polishing process is terminated, a flat polishing process of steps 6-1 to 6-19 (see FIGS. 25 to 27) is performed. Processes of steps 6-1 to 6-19, which will not be particularly described, are the same as those of the steps 5-3 to 5-21. The flat polishing process includes a process of determining a plurality of film thicknesses at a plurality of measurement points on the substrate W based on the film thickness of the reference film data calculated based on the second relational expression.

In step 6-2, the operation controller 9 allocates the film thickness of the reference film data determined in the step 6-1 which is calculated based on the second relational expression to the film thickness at each of the measurement points. In other words, the operation controller 9 determines that the film thickness of the reference film data determined in the step 6-1 which is calculated based on the second relational expression is the film thickness at the measurement point where the film measurement data corresponding to the reference film data has been obtained. The more specific process of the step 6-2 is the same as the step 5-4 except that the film thickness corresponding to the reference film data is determined based on the second relational expression.

In steps 6-9, 6-14, and 6-18, the operation controller 9 compares the film thickness of the substrate W with a predetermined final film thickness (a predetermined target film thickness). When the film thickness of the substrate W has reached the final film thickness, the operation controller 9 determines a polishing end point which is a point in time at which the film thickness has reached the final film thickness, and instructs the polishing apparatus to terminate the polishing of the substrate W. Specifically, the operation controller 9 compares the average film-thickness of the entire substrate W with the predetermined final film thickness. When the average film-thickness of the entire substrate W has reached the final film thickness, the operation controller 9 instructs the polishing apparatus to terminate the polishing of the substrate W.

If the polishing rate of the substrate W during the flat polishing process can be assumed to be constant, in the steps 6-9, 6-14, and 6-18, the operation controller 9 may compare a present polishing time (a polishing time from the step 6-1 to the present time) with a predetermined end polishing time. When the operation controller 9 determines that the present polishing time has reached the end polishing time, the operation controller 9 may instruct the polishing apparatus to terminate the polishing of the substrate W. The end polishing time is a polishing time when the film thickness reaches the final film thickness, and is determined based on the asperity-eliminated film-thickness, the final film thickness, and a polishing rate after the elimination of the surface asperities. In steps 6-10, 6-15, and 6-19, the operation controller 9 accumulates the correlation between the film-thickness profile and the torque waveform and/or the target film waveform into the memory 9a of the operation controller 9, and instructs the polishing apparatus to terminate the polishing of the substrate W.

In one embodiment, the steps 6-5 to 6-8 may not be performed, and the step 6-9 may be performed after the step 6-4. Further, in one embodiment, the step 6-9 may be performed after the step 6-5. Furthermore, in one embodiment, the steps 6-13 and 6-17 may not be performed, and the steps 6-14 and 6-18 may be performed after the steps 6-12 and 6-16.

As described above, the polishing apparatus of this embodiment changes the relational expression to be used for determining the film thickness of the substrate W during polishing depending on the surface configuration of the substrate W. Further, the polishing apparatus compares the torque waveform produced during polishing with the reference torque waveform obtained before polishing, and determines the timing to change the above-mentioned relational expression. Therefore, the film thickness of the substrate being polished is accurately measured even when the substrate has asperities in its surface. As a result, a uniformity of the film thickness and a detecting performance of the end point can be improved.

In one embodiment, if it becomes necessary to modify the first relational expression and/or the second relational expression, the first relational expression and/or the second relational expression may be corrected based on the results obtained in the processes described with reference to FIGS. 22 to 27. Further, in one embodiment, the reference substrate may be polished by the same processes as the processes described with reference to FIGS. 11 and 12, and the first relational expression and/or the second relational expression may be regenerated.

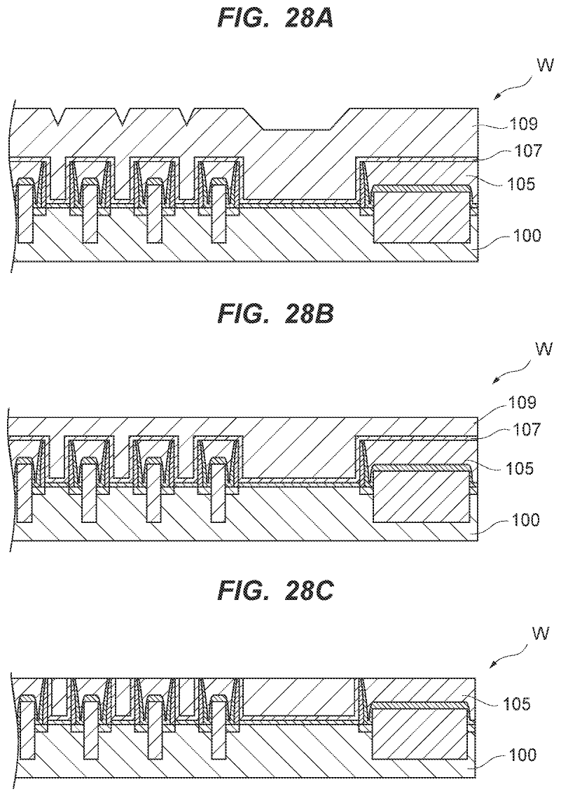

The above-described polishing method can be applied to substrates shown in FIGS. 28 to 30. FIGS. 28 to 30 are cross-sectional views showing other embodiments of the substrate W having the asperities in its surface. FIGS. 28A, 29A, and 30A show substrates before polishing, FIGS. 28B, 29B, and 30B show substrates after a top layer film (a tungsten (W) film 109, a dielectric film 111, or a tungsten (W) film 117) is polished to the asperity-eliminated film-thickness, and FIGS. 28C, 29C, and 30C show substrates that have been polished to the polishing end point.

FIG. 28 shows a cross section of a replacement gate. The substrate W shown in FIG. 28 has a silicon (Si) layer 100 having surface asperities, a dielectric film 105 formed above the silicon layer 100, a liner film 107 formed on the dielectric film 105, the liner film 10 being made of titanium nitride (TiN), and a tungsten (W) film 109 formed on the liner film 107. Since the tungsten (W) film 109 is a metal film, an eddy-current sensor is used as the film-thickness sensor 20 when the substrate W shown in FIG. 28 is polished.

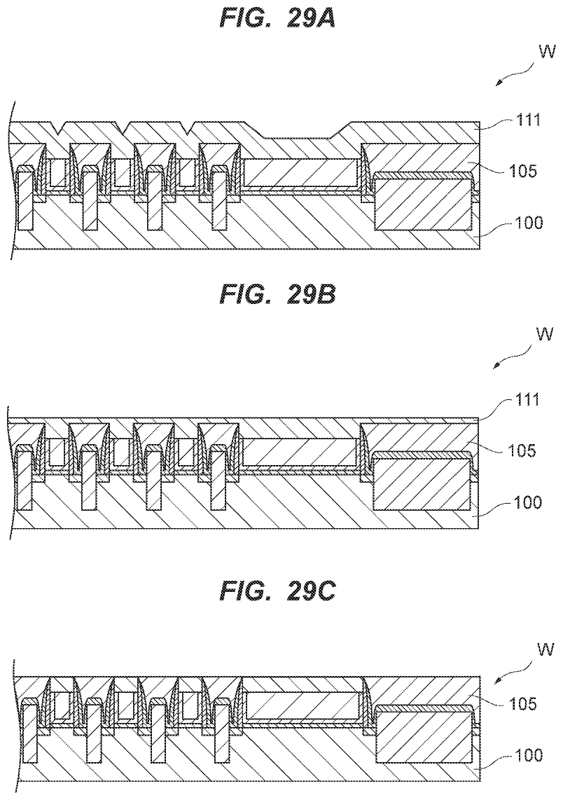

FIG. 29 shows a cross section of SAC (self-aligned contact) nitride. In the substrate W shown in FIG. 29, after the tungsten (W) film 109 of the substrate W shown in FIG. 28 is recessed by etching, a dielectric film (e.g., silicon nitride (Si₃N₄)) 111 is formed. An optical film-thickness sensor is used as the film-thickness sensor 20 when the substrate W shown in FIG. 29 is polished.

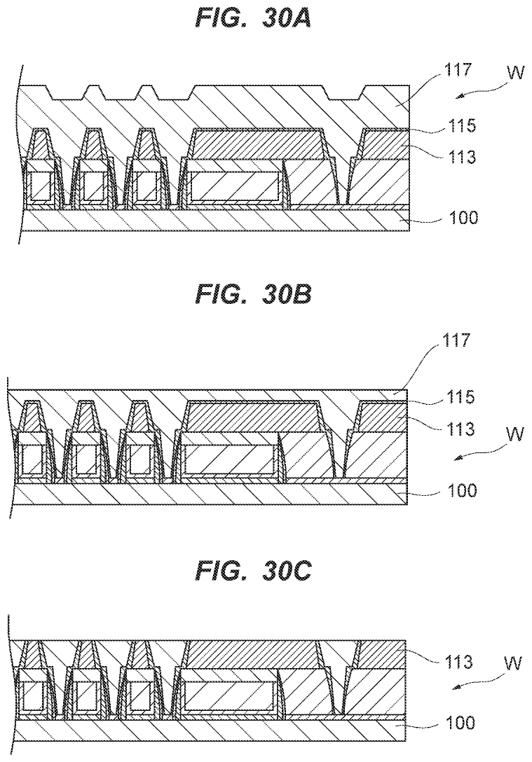

FIG. 30 shows a cross section of a contact portion. The substrate W shown in FIG. 30 has a silicon (Si) layer 100, a dielectric film 113 formed above the silicon layer 100, a liner film 115 formed on the dielectric film 113, the liner film 115 being made of titanium nitride (TiN), and a tungsten (W) film 117 formed on the liner film 115.

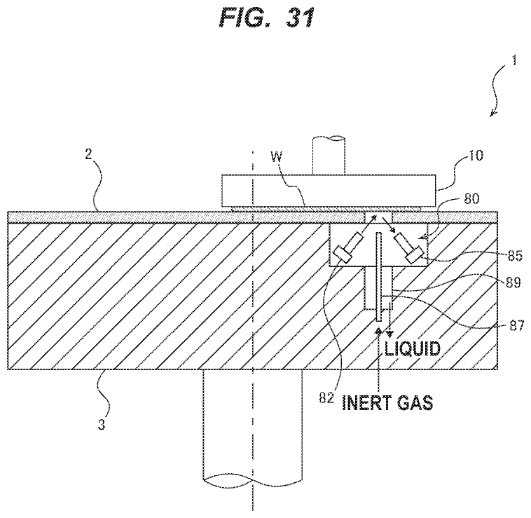

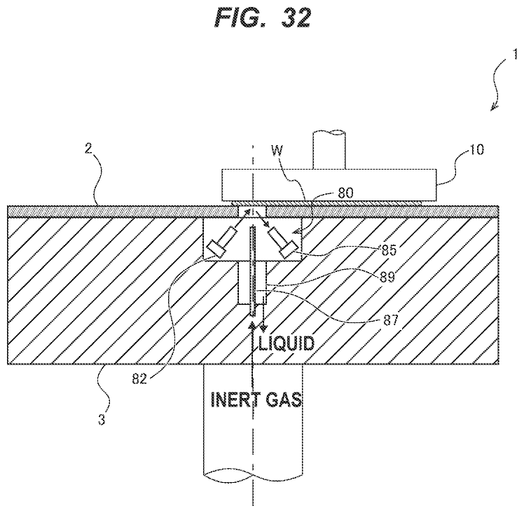

FIG. 31 is a schematic diagram showing another embodiment of the polishing apparatus. Configurations and operations of this embodiment, which will not be particularly described, are the same as those of the embodiments shown in FIGS. 1 to 27, and duplicated descriptions will be omitted. In FIG. 31, depiction of some components is omitted. In this embodiment, the film-thickness measuring device 80 is attached to the polishing table 3. The film-thickness measuring device 80 of this embodiment is more compact than the film-thickness measuring device 80 described with reference to FIG. 1.

The film-thickness measuring device 80 of this embodiment includes a light-emitting device 82 configured to direct light to the substrate W, and a light-receiving device 85 configured to receive reflected light from a surface (a surface to be polished) of the substrate W. The light-emitting device 82 includes a light source (not shown) configured to emit the light. In this embodiment, the light-emitting device 82 is arranged so as to irradiate the substrate W with the light from obliquely below, and the light-receiving device 85 is arranged obliquely with respect to the surface of the substrate W. However, arrangements of the light-emitting device 82 and the light-receiving device 85 are not limited to this arrangement. In one embodiment, the film-thickness measuring device 80 may be an eddy-current-type film-thickness measuring device including an eddy-current sensor, instead of the light-emitting device 82 and the light-receiving device 85.

In the example shown in FIG. 31, an ellipsometer is used as the film-thickness measuring device 80. Principle of the ellipsometer is a generally known principle. In this embodiment, in order to apply for the substrate W supported by the polishing head 10, it is necessary to remove liquid from a measurement portion and measure a polarization condition of the reflected light. Thus, in order to keep the measurement portion dry, the film-thickness measuring device 80 further includes a gas supply nozzle 87 configured to supply gas, such as CDA (clean dry air), nitrogen (N₂), argon (Ar), air, to the surface of the substrate W, and a liquid discharge passage 89 configured to discharge liquid, such as a polishing liquid (e.g., slurry), for use in polishing of the substrate W. The substrate W is supported by the polishing head 10, so that the substrate W can rotate and can move in X/Y directions. A film-thickness distribution can be determined by measuring multiple arbitrary points on the substrate W while the substrate W is being rotated. In order to protect a surface condition of the substrate W, portions other than the measurement portion can be immersed in the liquid.

The light-emitting device 82, the light-receiving device 85, the gas supply nozzle 87, and the liquid discharge passage 89 are attached to the polishing table 3, and rotate together with the polishing table 3 and the polishing pad 2. In this embodiment, each time the film-thickness measuring device 80 sweeps across the substrate W, the light-emitting device 82 emits the light to a plurality of measurement points on the rotating substrate W, and the light-receiving device 85 receives the reflected light from the plurality of measurement points. When the film-thickness measuring device 80 is the eddy-current-type film-thickness measuring device, the eddy-current sensor generates eddy current at the plurality of measurement points on the substrate W, and detects the eddy current at these measurement points. In one embodiment, as shown in FIG. 32, the film-thickness measuring device 80 may be arranged in a center portion of the polishing table 3.

According to this embodiment, the film thickness or the film-thickness profile of the substrate W can be measured by the film-thickness measuring device 80 without removing the substrate W from the polishing head 10. This configuration provides advantages, such as reducing time loss due to removal of the substrate W (improving throughput), preventing position deviation or tilt deviation due to reinstallation of the substrate W, reduction of measurement coordinate error, ease of rework after measurement, improvement of calibration accuracy of the output of the sensor for end-point detection (the film-thickness sensor 20), and reduction of particle adhesion due to removal or transfer of the substrate W.

In this embodiment, the film-thickness measuring device 80 can be combined with the detection of the asperity-eliminated point using the drive currents of the table motor 6, the polishing-head motor 17, and the oscillation motor 18, and the end-point detection using the film-thickness sensor 20. When using the film-thickness sensor 20, calibration of the film-thickness sensor 20 is required. Therefore, calibration to determine a correlation between the substrate W whose film thickness has been measured and the output of the sensor for the end-point detection is required. If the film-thickness measuring device 80 is an ITM (an ex-situ film-thickness measuring device) installed away from the polishing module 1, the substrate W is removed from the polishing head 10 for the calibration, and is transported to the ITM by the transfer robots 66, 69, etc. If the film-thickness measuring device 80 is the ITM installed away from the polishing module 1, an error factor may occur due to an error of a measurement position of the film thickness, polishing of the substrate multiple times, measuring of the film-thickness by the ITM, or obtaining of an output from the film-thickness sensors 20 at a plurality of points. In this embodiment, such error factors can be reduced. Therefore, a higher accurate calibration can be achieved than conventional way, so that improvement of the accuracy of the end-point detection can be achieved.

Furthermore, in this embodiment, a region of a high-density wiring portion of the substrate W can be identified, and a film-thickness distribution and accuracy can be determined based on film measurement results of the identified region. Since the substrate W does not require to be removed from the polishing head 10, after measuring the correlation between the coordinates of the substrate W and the film thickness, comparing of the output signal of the film-thickness sensor 20 can be performed with a small coordinate position error. Therefore, the relationship between the change in the signal of the film-thickness sensor 20, the coordinate position of the substrate W, and the film thickness can be determined with higher accuracy than conventionally way. This embodiment can be used particularly effectively in a case of a wafer having a complicated pattern structure. For example, this embodiment may be for use in film measuring using only a waveform of an effective region.

This embodiment is further applicable to various process pattern films, such as an oxide film, a nitride film, a metal film, a pattern film mixed thereof, a film of STI process or SAC process. In one embodiment, the film-thickness measuring device 80 described with reference to FIGS. 31 and 32 may be a film-thickness measuring device using a processing method of a camera image, a multispectral camera, or a hyperspectral camera. Further, in one embodiment, the film-thickness measuring device 80 may be a film-thickness measuring device using image processing or an optical interference method.

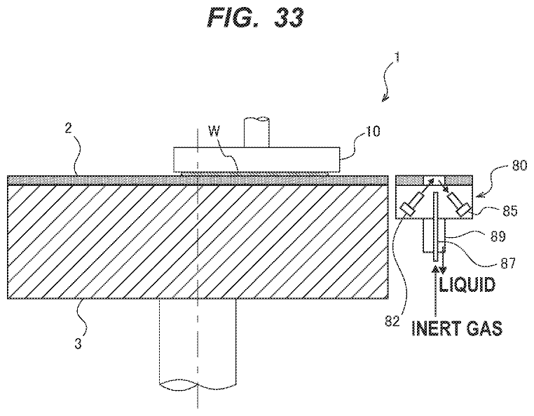

Furthermore, in one embodiment, as shown in FIG. 33, the film-thickness measuring device 80 may be disposed beside (near) the polishing table 3. When the film-thickness measuring device 80 is disposed near the polishing table 3, measuring can be performed without immersion in the liquid. Further, in order to prevent the surface of the substrate W from surface oxidation, only the measurement portion can be dried by forming a liquid film on the surface of the substrate W while liquid or mist is emitted from the gas supply nozzle 87. Furthermore, in one embodiment, in order to achieve a more compact film-thickness measuring device, measuring devices or mechanisms may be constituted by MEMS (micro electro mechanical systems). Connections of the light-emitting device 82 and the light-receiving device 85 can be of a direct connection type or a fiber connection type.

An advantage of disposing the film-thickness measuring device 80 in the polishing table 3 or near the polishing table 3 is that the film thickness can be measured with the substrate W being supported by the polishing head 10 without removing the substrate W from the polishing head 10. Other advantages include reduction of time loss due to removal of the substrate W (improvement of throughput), reduction of position deviation or tilt deviation of the substrate W due to reinstallation of the substrate W on the polishing head 10, reduction of measurement coordinate error, ease of rework of the substrate W after measurement, improvement of calibration accuracy of the output of the sensor for end-point detection, and reduction of particle adhesion due to removal or transfer of the substrate W.

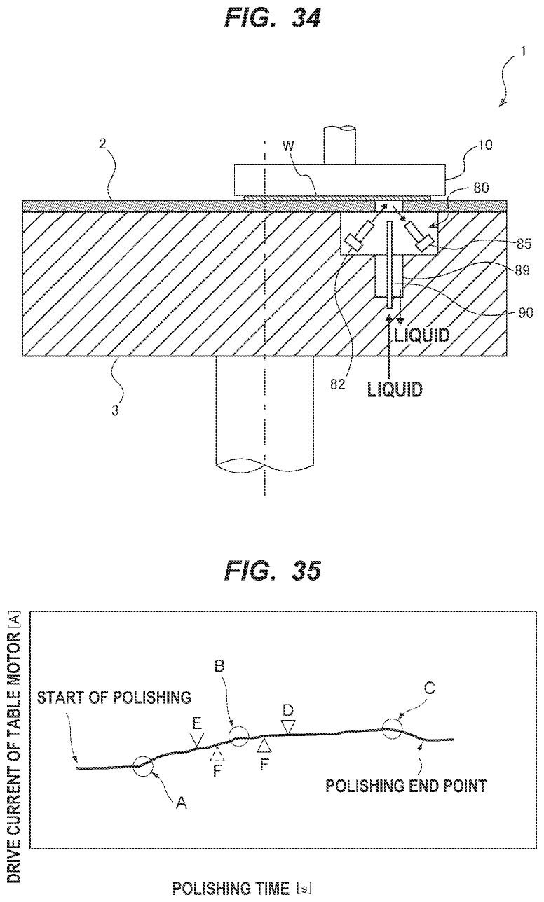

FIG. 34 is a cross-sectional view showing still another embodiment of the film-thickness measuring device 80. In this embodiment, the film-thickness measuring device 80 supplies liquid (e.g., pure water, chemical liquid, or slurry) to a film-thickness measurement region through a liquid supply nozzle 90, and measures an interference condition of the reflected light from the substrate W when the film-thickness measurement region is immersed in the liquid. While the liquid is supplied through the liquid supply nozzle 90, the liquid is discharged through the liquid discharge passage 89, so that the liquid is refreshed to remove impurities. The substrate W is supported by the polishing head 10, so that the substrate W can be rotated and translated. For example, film thicknesses at multiple arbitrary points on the substrate W can be measured while the substrate W is rotated by the polishing head 10, so that a film-thickness distribution can be determined. In one embodiment, the film-thickness measuring device 80 shown in FIG. 34 may be disposed beside (near) the polishing table 3.

FIG. 35 is a diagram showing an embodiment of a method of polishing a substrate having asperities in its surface. Generally, when a condition of an exposed surface of a substrate changes (e.g., when an exposed film is removed until an underlying film is exposed, or when asperities of the exposed surface are eliminated), polishing condition for the substrate is changed. The polishing condition for the substrate includes, for example, a pressing force on the substrate against the polishing surface of the polishing pad. The embodiment described below provides a method of determining a changing point of the polishing condition based on the asperity-eliminated point and a film-thickness measuring point before or after the asperity-eliminated point. Configurations and operations of this embodiment, which will not be particularly described, are the same as those of the previously described embodiments, and duplicated descriptions will be omitted.

The above-described polishing apparatus starts polishing of a reference substrate (or a reference wafer) having the same multilayered structure as a substrate W (a target wafer or a target substrate). During a period from the polishing start to a polishing end of the reference substrate, the polishing of the reference substrate is temporarily interrupted at least twice, and the film thickness of the reference substrate is measured by the film-thickness measuring device 80. More specifically, the film-thickness measuring device 80 measures film thicknesses (i.e., a film-thickness profile) at a plurality of measurement points on the reference substrate. After the film thicknesses are measured by the film-thickness measuring device 80, the polishing of the reference substrate is started again, and the reference substrate is polished until the polishing end point is finally reached. In this manner, the film thicknesses (i.e., the film-thickness profile) of the reference substrate are measured multiple times by the film-thickness measuring device 80.

The operation controller 9 produces a first torque waveform as shown in FIG. 35. The first torque waveform represents a change in torque required for polishing the reference substrate by the polishing apparatus (e.g., the polishing table 3 and/or the polishing head 10) along polishing time. Further, the operation controller 9 determines an asperity-eliminated point B from a feature point of the first torque waveform. This feature point is, for example, a point where the slope of the waveform changes beyond a threshold value. The first torque waveform is stored into the memory 9a of the operation controller 9.

Reference symbols D and E in FIG. 35 indicate film-thickness measuring points at which the film thicknesses at the plurality of measurement points on the reference substrate have been measured by the film-thickness measuring device 80. The film-thickness measuring point D is a point in time after the surface asperities of the reference substrate are eliminated, and the film-thickness measuring point E is a point in time before the surface asperities of the reference substrate are eliminated. Whether the surface asperities have been eliminated can be determined from the film-thickness profile of the reference substrate.

Further, the operation controller 9 determines a polishing-condition changing point F located between either the film-thickness measuring point D or the film-thickness measuring point E and the asperity-eliminated point B. In one example, the polishing-condition changing point F is determined based on a predetermined time from the asperity-eliminated point B or a change in the first torque waveform.

Next, the substrate W, which is the target substrate, is polished by the above-described polishing apparatus. The operation controller 9 produces a second torque waveform during polishing of the substrate W. The second torque waveform represents a change in torque required for polishing the substrate W by the polishing apparatus (e.g., the polishing table 3 and/or the polishing head 10) along polishing time. Since the substrate W and the reference substrate have the same multilayered structure, the first torque waveform and the second torque waveform have similar shapes. The operation controller 9 determines a point on the second torque waveform that coincides with the polishing-condition changing point F while producing the second torque waveform, and changes the polishing condition of the substrate W at the determined point. According to the present embodiment, the optimum changing point of the polishing condition can be determined from the asperity-eliminated point and the film-thickness measuring point of the reference substrate.

The embodiment of determining the polishing-condition changing point F located between the film-thickness measuring point D and the asperity-eliminated point B, i.e., after the asperity-eliminated point B, is effective when the change in the elimination of the surface asperities is gentle. In other words, the embodiment is effective in a case where the condition of the elimination of the surface asperities or the film-thickness distribution is not problematic (i.e., the surface asperities are sufficiently eliminated or the film thickness is highly uniform) at the film-thickness measuring point D.

The embodiment of determining the polishing-condition changing point F located between the film-thickness measuring point E and the asperity-eliminated point B, i.e., before the asperity-eliminated point B, is effective when the change in the elimination of the surface asperities is rapid. Furthermore, if the non-uniformity of the film-thickness distribution becomes large at the film-thickness measuring point D, or if deterioration in the specification is observed, the operation controller 9 determines the polishing-condition changing point F located between the film-thickness measuring point E and the asperity-eliminated point B, i.e., before the asperity-eliminated point B.

In this way, the changing point of the polishing condition can be determined based on the change in the overall waveform and the speed of change before and after the changing point, so that efficient polishing with a high uniformity of the film-thickness distribution can be performed.

AI (artificial intelligence) can be for use in the waveform prediction. The polishing-condition changing point can be determined while the waveform prediction is performed by a trained model that has learned using a dataset of accumulated data.

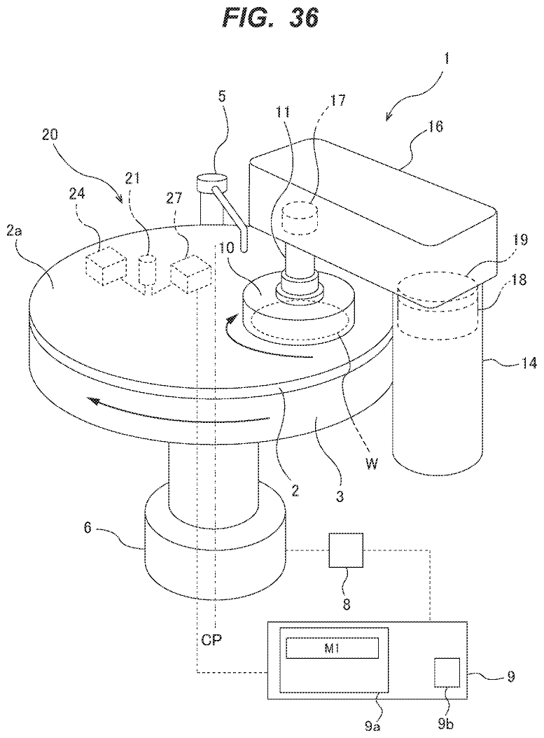

Next, an embodiment of a polishing method including predicting the elimination of the surface asperities of the substrate W using a trained model will be described with reference to FIG. 36. Configurations and operations of this embodiment, which will not be particularly described, are the same as those of the above-described embodiments, and duplicated descriptions will be omitted.

The operation controller 9 has an asperity-elimination predicting model M1 stored in the memory 9a of the operation controller 9. The polishing apparatus polishes the substrate W by pressing the substrate W against the polishing surface 2a of the polishing pad 2 with the polishing head 10 while rotating the polishing table 3 supporting the polishing pad 2. During the polishing of the substrate W, the operation controller 9 produces a torque waveform indicating drive current of the motor required for moving the substrate W relative to the polishing surface 2a (i.e., the drive current waveform of the table motor 6, the drive current waveform of the polishing-head motor 17, or the drive current waveform of the oscillation motor 18), inputs the torque waveform into the asperity-elimination predicting model M1, and outputs an asperity-elimination index of the surface of the substrate W from the asperity-elimination predicting model M1.

The asperity-elimination index is a degree of the elimination of the surface asperities (which may be expressed by %, level, time to asperity-eliminated point, etc.) calculated by the asperity-elimination predicting model M1 from the present torque waveform. Therefore, the operation controller 9 can calculate a difference between the present surface asperities of the substrate W and the asperity-eliminated point based on the degree of elimination of the surface asperities. The operation controller 9 may change the polishing condition for the substrate W when the asperity-eliminated point is reached.

The asperity-elimination predicting model M1 may be configured to further output at least one of a plurality of indexes listed below.
A point at which the polishing condition for the substrate W should be changed
A predicted torque waveform before or after the asperity-eliminated point
An alarm indicating an abnormality of the torque waveform
A difference (time, or waveform) between the torque waveforms at the asperity-eliminated point and at the present time
Recommendation of dressing of the polishing pad 2

The asperity-elimination predicting model M1 may be configured to further output at least one of a plurality of indexes of virtual metrology listed below.
A predicted film-thickness profile at the asperity-eliminated point
A predicted film-thickness profile before and after the asperity-eliminated point
A prediction of change in film-thickness profile between the present time and the asperity-eliminated point
A predicted timing of switching the polishing condition from one to another based on a change in film-thickness profile before and after the asperity-eliminated point

The asperity-elimination predicting model M1 is a trained model constructed by machine learning, such as deep learning, reinforcement learning, and quantum computing. The trained model is also called a tuned model or a tuned neural network. Training data for use in the machine learning include a plurality of training torque waveforms obtained when at least one training substrate is polished until its surface asperities are eliminated. More specifically, the operation controller 9 produces a plurality of training torque waveforms indicating drive current of the motor (i.e., the table motor 6, the polishing-head motor 17, or the oscillation motor 18) required for moving the training substrate relative to the polishing surface 2a, while the training substrate is polished until its surface asperities are eliminated. Further, the operation controller 9 constructs the asperity-elimination predicting model M1 by performing the machine learning using the training data including the plurality of training torque waveforms and a plurality of degrees of elimination of surface asperities as correct labels.

The torque waveform to be input to the asperity-elimination predicting model M1, which is the trained model or learned model, and the training torque waveform for use in the machine learning may be processed torque waveforms. Examples of the processed torque waveform include a torque waveform obtained by applying a filter to the torque waveform, and a torque waveform obtained by amplifying the torque waveform with an amplifier.

In one embodiment, the training data may further include the number of substrates that have been polished previously using the polishing pad 2. The operation controller 9 may be configured to input the number of substrates that have been polished previously using the polishing pad 2, in addition to the torque waveform, into the asperity-elimination predicting model M1. The number of substrates that have been polished previously using the polishing pad 2 is related to wear of the polishing pad 2, and is expected to affect the polishing time until the asperity-eliminated point is reached. Therefore, this embodiment can output a more accurate asperity-elimination index.

The input data to be input to the asperity-elimination predicting model M1 may further include at least one of the following data in addition to the torque waveform.
An output signal of the film-thickness sensor 20
A processed output signal of the film-thickness sensor 20
The number of substrates that have been polished previously using the polishing pad 2 after dressing of the polishing pad 2

The training data may further include at least one of the following input data.
The number of substrates that have been polished previously using the polishing pad 2 and polishing rates of the substrates
The number of substrates that have been polished previously using the polishing pad 2 and polishing rate profiles of the substrates
The number of substrates that have been polished previously using the polishing pad 2 after dressing of the polishing pad 2

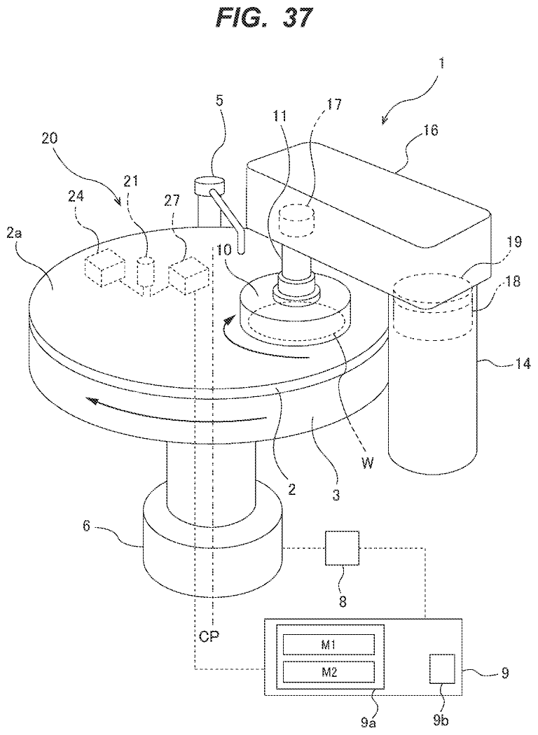

Next, another embodiment of the polishing method including predicting the elimination of the surface asperities of the substrate W using trained model will be described with reference to FIG. 37. Configurations and operations of this embodiment, which will not be particularly described, are the same as those of the embodiment described with reference to FIG. 36, and duplicated descriptions will be omitted.

As shown in FIG. 37, the operation controller 9 has a polishing-end-point predicting model M2 stored in the memory 9a of the operation controller 9, in addition to the asperity-elimination predicting model M1. During the polishing of the substrate W, the operation controller 9 is configured to input the torque waveform into the polishing-end-point predicting model M2 and output a polishing-end-point index of the substrate W from the polishing-end-point predicting model M2. The torque waveform to be input to the polishing-end-point predicting model M2 is the same as the torque waveform to be input to the asperity-elimination predicting model M1. The polishing-end-point index is an index (expressed with %, level, time to the polishing end point, etc.) that indicates a difference between the present time and the polishing end point.

The polishing-end-point predicting model M2 is a trained model constructed by machine learning, such as deep learning, reinforcement learning, and quantum computing. The trained model is also called a tuned model or a tuned neural network. Training data for use in the machine learning include a plurality of training torque waveforms (drive current waveforms of the table motor 6, drive current waveforms of the polishing-head motor 17, or drive current waveforms of the oscillation motor 18) obtained when at least one training substrate is polished until a polishing end point of the training substrate is reached. More specifically, the operation controller 9 produces a plurality of training torque waveforms indicating drive current of the motor (i.e., the table motor 6, the polishing-head motor 17, or the oscillation motor 18) required for moving the training substrate relative to the polishing surface 2a, while the training substrate is polished until its polishing end point is reached. Further, the operation controller 9 constructs the polishing-end-point predicting model M2 by performing the machine learning using the training data including the plurality of training torque waveforms and a plurality of polishing-end-point indexes as correct labels.

The polishing apparatus polishes the substrate W by pressing the substrate W against the polishing surface 2a of the polishing pad 2 with the polishing head 10 while rotating the polishing table 3 supporting the polishing pad 2. During the polishing of the substrate W, the operation controller 9 produces a torque waveform indicating drive current of the motor (i.e., the drive current waveform of the table motor 6, the drive current waveform of the polishing-head motor 17, or the drive current waveform of the oscillation motor 18) required for moving the substrate W relative to the polishing surface 2a, inputs the torque waveform into the asperity-elimination predicting model M1 (the trained model), and outputs an asperity-elimination index of the surface of the substrate W from the asperity-elimination predicting model M1. Further, the operation controller 9 inputs the torque waveform into the polishing-end-point predicting model M2, and outputs a polishing-end-point index of the substrate W from the polishing-end-point predicting model M2.

The torque waveform to be input to the polishing-end-point predicting model M2, which is the trained model or learned model, and the training torque waveform for use in the machine learning may be processed torque waveforms. Examples of the processed torque waveform include a torque waveform obtained by applying a filter to the torque waveform, and a torque waveform obtained by amplifying the torque waveform with an amplifier.

In one embodiment, the training data for use in the machine learning for constructing the polishing-end-point predicting model M2 may further include the number of substrates that have been polished previously using the polishing pad 2. The operation controller 9 may be configured to input the number of substrates that have been polished previously using the polishing pad 2, in addition to the torque waveform, into the polishing-end-point predicting model M2. The number of substrates that have been polished previously using the polishing pad 2 is related to wear of the polishing pad 2, and is expected to affect the polishing time until the polishing end point is reached. Therefore, this embodiment can output a more accurate polishing-end-point index.

The input data to be input to the polishing-end-point predicting model M2 may further include the following data in addition to the torque waveform.
An output signal of the film-thickness sensor 20
A processed output signal of the film-thickness sensor 20
The number of substrates that have been polished previously using the polishing pad 2 after dressing of the polishing pad 2

The training data for use in the machine learning for constructing the polishing-end-point predicting model M2 may further include the following input data.
The number of substrates that have been polished previously using the polishing pad 2 and polishing rates of the substrates
The number of substrates that have been polished previously using the polishing pad 2 and polishing rate profiles of the substrates
The number of substrates that have been polished previously using the polishing pad 2 after dressing of the polishing pad 2

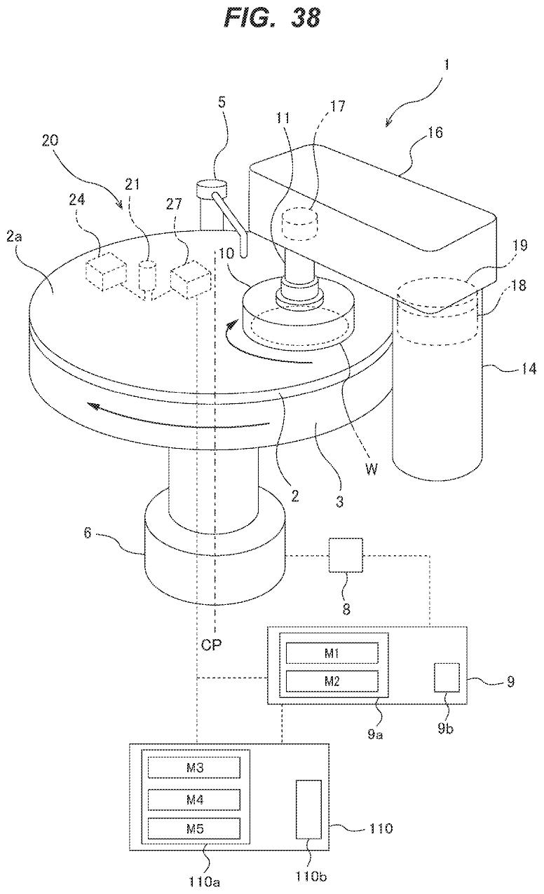

Next, another embodiment of the polishing method including predicting the elimination of surface asperities of the substrate W using trained model will be described with reference to FIG. 38. Configurations and operations of this embodiment, which will not be particularly described, are the same as those of the embodiment described with reference to FIG. 37, and duplicated descriptions will be omitted. The polishing apparatus shown in FIG. 38 further includes a virtual polishing apparatus 110 configured to virtually polish the substrate W in virtual space. This virtual polishing apparatus 110 is coupled to the film-thickness sensor 20, and receives a film-thickness signal indicating the film thickness of the substrate W from the film-thickness sensor 20 during the polishing of the substrate W.

The virtual polishing apparatus 110 includes a memory 110a storing programs therein, and a processor 110b configured to perform arithmetic operations according to instructions contained in the programs. The processor 110b includes a CPU (central processing unit), a GPU (graphic processing unit), or the like that performs arithmetic operations according to the instructions contained in the programs stored in the memory 110a. The memory 110a includes a main memory (e.g., a random access memory) that can be accessed by the processor 110b, and an auxiliary memory (e.g., a hard disk drive or a solid state drive) that stores data and the programs. The virtual polishing apparatus 110 is composed of at least one computer.

However, the specific configuration of the virtual polishing apparatus 110 is not limited to this example.

The virtual polishing apparatus 110 is coupled to the operation controller 9. The asperity-elimination index output from the asperity-elimination predicting model M1 of the operation controller 9 is transmitted to the virtual polishing apparatus 110. Further, the polishing-end-point index output from the polishing-end-point predicting model M2 of the operation controller 9 is transmitted to the virtual polishing apparatus 110.

The virtual polishing apparatus 110 has an initial film-thickness profile model M3, an asperity-eliminated film-thickness profile model M4, and a polishing-end-point film-thickness profile model M5 stored in the memory 110a of the virtual polishing apparatus 110. The virtual polishing apparatus 110 receives a film-thickness signal indicating the film thickness of the substrate W from the film-thickness sensor 20, inputs the film-thickness signal into the initial film-thickness profile model M3, and outputs a virtual initial film-thickness profile of the substrate W from the initial film-thickness profile model M3.

When the asperity-elimination index output from the asperity-elimination predicting model M1 of the operation controller 9 indicates that the surface asperities of the substrate W have been eliminated, the virtual polishing apparatus 110 inputs the film-thickness signal received from the film-thickness sensor 20 into the asperity-eliminated film-thickness profile model M4, and outputs a virtual asperity-eliminated film-thickness profile of the substrate W from the asperity-eliminated film-thickness profile model M4.

When the polishing-end-point index output from the polishing-end-point predicting model M2 of the operation controller 9 indicates that the polishing end point of the substrate W has been reached, the virtual polishing apparatus 110 inputs the film-thickness signal received from the film-thickness sensor 20 into the polishing-end-point film-thickness profile model M5, and output a virtual polishing-end-point film-thickness profile of the substrate W from the polishing-end-point film-thickness profile model M5.

The initial film-thickness profile model M3, the asperity-eliminated film-thickness profile model M4, and the polishing-end-point film-thickness profile model M5 are trained models constructed by machine learning, such as deep learning, reinforcement learning, or quantum computing.

The operation controller 9 and the virtual polishing apparatus 110 can perform processes in parallel. Specifically, the operation controller 9 can calculate the asperity-elimination index and the polishing-end-point index using the asperity-elimination predicting model M1 and the polishing-end-point predicting model M2, respectively, while the virtual polishing apparatus 110 can generate the virtual initial film-thickness profile, the virtual asperity-eliminated film-thickness profile, and the virtual polishing-end-point film-thickness profile using the initial film-thickness profile model M3, the asperity-eliminated film-thickness profile model M4, and the polishing-end-point film-thickness profile model M5, respectively.

In one embodiment, the virtual polishing apparatus 110 may have either the asperity-eliminated film-thickness profile model M4 or the polishing-end-point film-thickness profile model M5. Further, in one embodiment, the virtual polishing apparatus 110 may be configured to calculate the virtual initial film-thickness profile, the virtual asperity-eliminated film-thickness profile, and the virtual polishing-end-point film-thickness profile by simulations, instead of the initial film-thickness profile model M3, the asperity-eliminated film-thickness profile model M4, and the polishing-end-point film-thickness profile model M5.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a polishing method and a polishing apparatus for polishing a substrate, such as a wafer.

### REFERENCE SIGNS LIST

1 polishing module
2 polishing pad
2a polishing surface
3 polishing table
5 polishing-liquid supply nozzle
6 table motor
8 torque measuring device
9 operation controller
10 polishing head
11 head shaft
13 head body
14 support shaft
15 rotary joint
16 oscillation arm
17 polishing-head motor
18 oscillation motor
19 angle detector
20 film-thickness sensor
21 optical sensor head
24 light source
27 spectrometer
40 retainer ring
42 drive ring
45 elastic membrane
46, 47, 48, 49 pressure chamber
50 retaining-ring pressure chamber
52 retainer-ring pressing device
53 piston
54 rolling diaphragm
60 housing
61 load-unload section
63 polishing section
64 swing transporter
65 load port
66 loader (transfer robot)
67 first temporary base
68 second temporary base
69 transfer robot
70 cleaning section
74 first cleaning module
75 second cleaning module
76 third cleaning module
77 drying module
78 linear transporter
80 film-thickness measuring device
82 light-emitting device
85 light-receiving device
87 gas supply nozzle
89 liquid discharge passage
90 liquid supply nozzle
100 silicon layer
10 stopper layer
102 dielectric film
110 virtual polishing apparatus
R1, R2, R3, R4, R5 pressure regulator

1. A polishing method comprising:
polishing a substrate by pressing the substrate with a polishing head against a polishing surface of a polishing pad while rotating a polishing table supporting the polishing pad;
producing a torque waveform while polishing the substrate; and
selecting one reference torque waveform from a plurality of reference torque waveforms accumulated before the polishing of the substrate,
wherein producing the torque waveform comprises producing a torque waveform from a measurement value of a torque for rotating the polishing table, a measurement value of a torque for rotating the polishing head about an axis thereof, or a measurement value of a torque for oscillating the polishing head along the polishing surface,
polishing the substrate includes an asperity polishing process of polishing the substrate before a film thickness of the substrate reaches an asperity-eliminated film-thickness, and a flat polishing process performed after the asperity polishing process,
the asperity polishing process includes:
determining a plurality of film thicknesses at a plurality of measurement points on the substrate based on a film thickness of reference film data calculated based on a first relational expression; and
comparing the torque waveform with the selected reference torque waveform to determine whether the asperity polishing process should be terminated, and
the flat polishing process includes determining a plurality of film thicknesses at a plurality of measurement points on the substrate based on a film thickness of reference film data calculated based on a second relational expression.

2. The polishing method according to claim 1, wherein selecting one reference torque waveform from the plurality of reference torque waveforms accumulated before the polishing of the substrate comprises selecting one reference torque waveform from the plurality of reference torque waveforms based on a film-thickness profile of the substrate before polishing and a type of the substrate.

3. The polishing method according to claim 1, wherein determining whether the asperity polishing process should be terminated comprises determining that the asperity polishing process should be terminated when a present torque of the torque waveform has reached an asperity-eliminated point estimated from the selected reference torque waveform.

4. The polishing method according to claim 1, wherein determining whether the asperity polishing process should be terminated includes:
after a predetermined period of time has elapsed, comparing a shape of the torque waveform with a shape of the selected reference torque waveform till a polishing time corresponding to a present polishing time, and calculating a degree of coincidence of the shape of the torque waveform and the shape of the selected reference torque waveform;
comparing the calculated degree of coincidence with a predetermined reference degree of coincidence, and when the calculated degree of coincidence is more than or equal to the predetermined reference degree of coincidence, calculating a difference between a polishing time at an asperity-eliminated point estimated from the selected reference torque waveform and the present polishing time; and
determining that the asperity polishing process should be terminated when polishing time of the substrate has reached a time that is calculated by adding the present polishing time to the difference or a value obtained by multiplying the difference by a coefficient.

5. The polishing method according to claim 1, further comprising:
after a predetermined period of time has elapsed, comparing a shape of the torque waveform with a shape of the selected reference torque waveform till a polishing time corresponding to a present polishing time, and calculating a degree of coincidence of the shape of the torque waveform and the shape of the selected reference torque waveform; and
comparing the calculated degree of coincidence with a predetermined reference degree of coincidence, and when the calculated degree of coincidence is less than or equal to the predetermined reference degree of coincidence, changing a polishing condition.

6. A polishing apparatus comprising:
a polishing table configured to support a polishing pad;
a table motor configured to rotate the polishing table;
a polishing head having a plurality of pressure chambers configured to press a substrate against a polishing surface of the polishing pad;
a film-thickness sensor configured to output a film-thickness signal that varies according to a film thickness of the substrate;
a plurality of pressure regulators coupled to the plurality of pressure chambers, respectively;
a torque measuring device configured to measure a torque for rotating the polishing table, a torque for rotating the polishing head, or a torque for oscillating the polishing head along the polishing surface; and
an operation controller configured to control the polishing apparatus,
wherein the operation controller is configured to produce a torque waveform from a measurement value of the torque for rotating the polishing table, a measurement value of the torque for rotating the polishing head, or a measurement value of the torque for oscillating the polishing head along the polishing surface,
the operation controller is configured to select one reference torque waveform from a plurality of reference torque waveforms accumulated before polishing of the substrate,
the operation controller is configured to perform an asperity polishing process of polishing the substrate before a film thickness of the substrate reaches an asperity-eliminated film-thickness, and a flat polishing process after the asperity polishing process,
the operation controller is configured to, during the asperity polishing process, determine a plurality of film thicknesses at a plurality of measurement points on the substrate based on a film thickness of reference film data calculated based on a first relational expression,
the operation controller is configured to, during the asperity polishing process, compare the torque waveform with the selected reference torque waveform and is configured to determine whether the asperity polishing process should be terminated, and
the operation controller is configured to, during the flat polishing process, determine a plurality of film thicknesses at a plurality of measurement points on the substrate based on a film thickness of reference film data calculated based on a second relational expression.

7. The polishing apparatus according to claim 6, wherein the operation controller is configured to select one reference torque waveform from the plurality of reference torque waveforms based on a film-thickness profile of the substrate before polishing and a type of the substrate.

8. The polishing apparatus according to claim 6, wherein the operation controller is configured to determine that the asperity polishing process should be terminated when a present torque of the torque waveform has reached an asperity-eliminated point estimated from the selected reference torque waveform.

9. The polishing apparatus according to claim 6, wherein the operation controller is configured to:
after a predetermined period of time has passed, compare a shape of the torque waveform with a shape of the selected reference torque waveform till a polishing time corresponding to a present polishing time;
calculate a degree of coincidence of the shape of the torque waveform and the shape of the selected reference torque waveform;
compare the calculated degree of coincidence with a predetermined reference degree of coincidence;
calculate a difference between polishing time at an asperity-eliminated point estimated from the selected reference torque waveform and the present polishing time when the calculated degree of coincidence is more than or equal to the predetermined reference degree of coincidence; and
determine that the asperity polishing process should be terminated when polishing time of the substrate has reached a time that is calculated by adding the present polishing time to the difference or a value obtained by multiplying the difference by a coefficient.

10. The polishing apparatus according to claim 6, wherein the operation controller is configured to:
after a predetermined period of time has passed, compare a shape of the torque waveform with a shape of the selected reference torque waveform till a polishing time corresponding to a present polishing time;
calculate a degree of coincidence of the shape of the torque waveform and the shape of the selected reference torque waveform;
compare the calculated degree of coincidence with a predetermined reference degree of coincidence; and
instruct the polishing apparatus to change a polishing condition when the calculated degree of coincidence is less than or equal to the predetermined reference degree of coincidence.

11. The polishing apparatus according to claim 6, wherein the film-thickness sensor comprises an optical film-thickness sensor or an eddy-current sensor.

12. The polishing apparatus according to claim 6, further comprising a film-thickness measuring device configured to measure a film thickness of the substrate, the film-thickness measuring device being attached to the polishing table.

13. A polishing method comprising:
polishing a substrate by pressing the substrate with a polishing head against a polishing surface of a polishing pad while rotating a polishing table supporting the polishing pad;
producing a torque waveform indicating drive current of a motor required for moving the substrate relative to the polishing surface while polishing the substrate;
inputting the torque waveform into an asperity-elimination predicting model; and
outputting an asperity-elimination index of a surface of the substrate from the asperity-elimination predicting model.

14. The polishing method according to claim 13, wherein the asperity-elimination predicting model comprises a trained model constructed by:
generating a plurality of training torque waveforms each indicating drive current of a motor required for moving a training substrate relative to the polishing surface while polishing the training substrate until surface asperities of the training substrate are eliminated; and
performing machine learning using training data including the plurality of training torque waveforms.

15. The polishing method according to claim 14, wherein
the training data further includes the number of substrates that have been polished previously using the polishing pad, and
the polishing method includes inputting the number of substrates that have been polished previously using the polishing pad, in addition to the torque waveform, into the asperity-elimination predicting model.

16. The polishing method according to claim 13, further comprising:
inputting the torque waveform into a polishing-end-point predicting model; and
outputting a polishing-end-point index of the substrate from the polishing-end-point predicting model.

17. The polishing method according to claim 13, further comprising:
virtually polishing the substrate in virtual space; and
generating a virtual film-thickness profile of the substrate.
